(19) United States
(12) Patent Application Publication
(10) Pub. No.: US 2015/0263028 A1
(43) Pub. Date: Sep. 17, 2015

(54) SEMICONDUCTOR MEMORY DEVICE

(71) Applicant: KABUSHIKI KAISHA TOSHIBA, Tokyo (JP)

(72) Inventors: Shoichi WATANABE, Yokkaichi Mie (JP); Koichi MATSUNO, Mie Mie (JP)

(21) Appl. No.: 14/559,666

(22) Filed: Dec. 3, 2014

Related U.S. Application Data
(60) Provisional application No. 61/952,348, filed on Mar. 13, 2014.

(51) Int. Cl. H01L 27/115; H01L 29/66; H01L 29/792

(52) U.S. Cl. CPC H01L 27/11575; H01L 29/792; H01L 29/66833; H01L 27/11565; H01L 27/1157; H01L 27/11573

(57) ABSTRACT

A semiconductor device includes a semiconductor substrate having a memory cell region and a peripheral circuit region, a plurality of adjacent memory gates formed on the semiconductor substrate via a tunnel insulating film in the memory cell region, a first insulating film covering the memory gates and having air gaps formed therein between the memory gates, a first barrier film on the first insulating film, a second insulating film above the semiconductor substrate in the peripheral circuit region, a second barrier film on the first barrier film and the second insulating film, and a third insulating film on the second barrier film and having first and second grooves, in which first and second wirings are respectively formed. A lower surface of the second wiring is closer to the upper surface of the semiconductor substrate in the peripheral circuit region than an upper surface of the second barrier film.

### CROSS-REFERENCE TO RELATED APPLICATION

This application is based upon and claims the benefit of priority from U.S. Provisional Patent Application No. 61/952,348, filed Mar. 13, 2014, the entire contents of which are incorporated herein by reference.

### FIELD

Embodiments described herein relate to a semiconductor memory device.

### BACKGROUND

In recent years, in order to reduce mutual interference between adjacent memory cells in a NAND flash memory, a structure including air gaps in a word line direction between cells (a word line air gap structure) is starting to be adopted. When using the word line air gap structure, there is a need for securing a degree of distance between air gaps and wirings which are disposed on the air gaps. Meanwhile, in peripheral circuits, there is a need for a reduction in variation of wiring resistance due to the circuit characteristics.

### BRIEF DESCRIPTION OF THE DRAWINGS

FIG. 1 is an example of an equivalent circuit diagram illustrating a portion of a memory cell array which is formed in a memory cell area of a semiconductor memory device according to first and second embodiments.

FIG. 2 is an example of a plan view which schematically illustrates a layout pattern of a portion of the memory cell area.

FIG. 3 is a block diagram illustrating an example of a configuration of NAND flash memory including peripheral circuits.

FIG. 4 is a block diagram illustrating an example of a buffer unit.

FIG. 5 is a circuit diagram illustrating an example of a modification example of the buffer unit.

FIG. 6A is an example of a layout of the memory cell area of the NAND flash memory according to the first and second embodiments; FIG. 6B is an example of the layout of a transistor forming area of a peripheral circuit unit; and FIG. 6C is an example of the layout of an ODT circuit unit of the peripheral circuit unit.

FIGS. 7A to 17A are examples of diagrams illustrating cross-sectional structures of the memory cell area of a NAND flash memory device according to the first embodiment.

FIGS. 7B to 17B are examples of diagrams illustrating the cross-sectional structures of transistors of the peripheral circuit unit according to the first embodiment.

FIGS. 7C to 17C are examples of diagrams illustrating a portion of the cross-sectional structures of the ODT circuit unit according to the first embodiment.

FIGS. 18A to 27A are examples of diagrams illustrating cross-sectional structures of a memory cell area M of a NAND flash memory device according to the second embodiment.

FIGS. 18B to 27B are examples of diagrams illustrating the cross-sectional structures of transistors of the peripheral circuit unit according to the second embodiment.

FIGS. 18C to 27C are examples of diagrams illustrating a portion of the cross-sectional structures of the ODT circuit unit according to the second embodiment.

FIGS. 28 and 29 are examples of diagrams schematically illustrating a configuration in which the transistor forming area and the ODT circuit unit of the peripheral circuit unit are connected.

### DETAILED DESCRIPTION

In general, according to one embodiment, a semiconductor device includes a memory cell region and a peripheral circuit region, a plurality of adjacent memory gates that are disposed on the semiconductor substrate via a tunnel insulating film in the memory cell region, a first insulating film covering the memory gates and having air gaps formed therein between the memory gates, a first barrier film on the first insulating film, a second insulating film above the semiconductor substrate in the peripheral circuit region, a second barrier film on the first barrier film and the second insulating film, and a third insulating film on the second barrier film and having a first groove, in which a first wiring is formed above the memory cell region, and a second groove in which a second wiring is formed above the peripheral circuit region. A distance between a lower surface of the first wiring and an upper surface of the semiconductor substrate in the memory cell region is larger than a distance between an upper surface of the first barrier film and the upper surface of the semiconductor substrate in the memory cell region, and a lower surface of the second wiring is closer to the upper surface of the semiconductor substrate in the peripheral circuit region than an upper surface of the second barrier film.

### First Embodiment

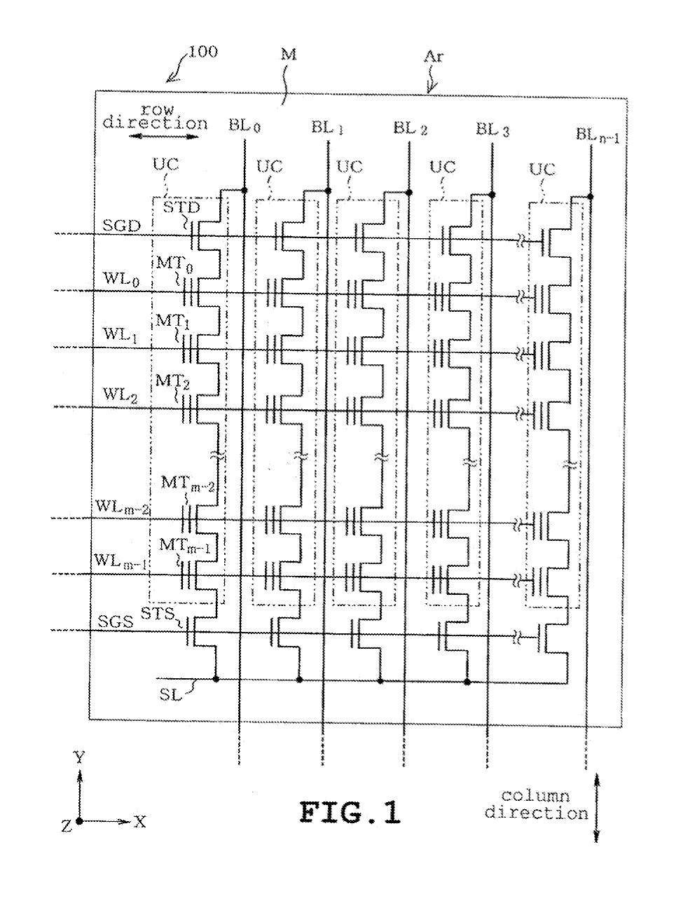

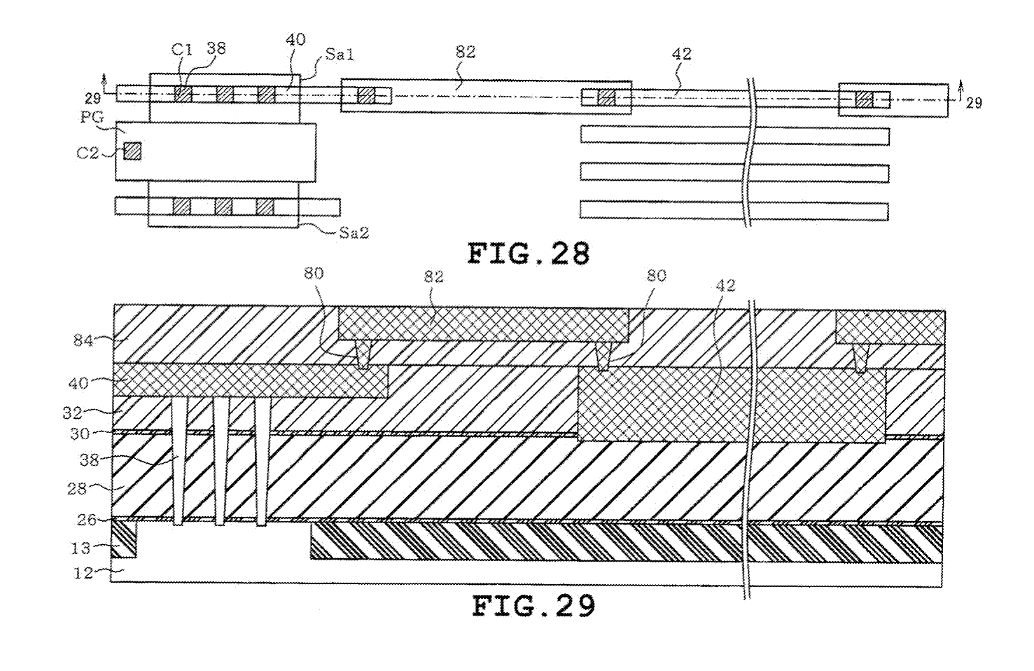

Hereinafter, description will be given of the NAND flash memory device as the semiconductor memory device to which the first embodiment is applied, with reference to FIG. 1 to FIG. 17, FIG. 28 and FIG. 29. In the description given hereinafter, the same reference numerals are applied to elements provided with the same function and configuration. The drawings are schematic, and the relationships between thickness and planar dimensions, the ratio of the thicknesses of each layer and the like do not necessarily match actual values. In addition, the directions, up, down, left and right indicate relative directions of a case in which a circuit forming surface side in the semiconductor substrate described hereinafter is “up”, and do not necessarily match directions based on a direction of gravitational acceleration. Note that, in the description given hereinafter, for convenience of illustration, an XYZ orthogonal coordinate system will be used. In this coordinate system, two directions which are parallel to the surface of the semiconductor substrate and are orthogonal to one another are the X direction and the Y direction. A direction which is orthogonal to both the X direction and the Y direction is the Z direction.

First, description will be given of the configuration of the NAND flash memory device of the semiconductor memory device according to the embodiments.

FIG. 1 is an example of an equivalent circuit diagram illustrating a portion of the memory cell array which is formed in the memory cell area of the semiconductor memory device according to the first embodiment. As illustrated in FIG. 1, a NAND flash memory device 100 includes a memory cell array Ar, in which multiple memory cells which are capable of writing and erasing electrical data are arranged in a matrix shape.

A plurality of unit memory cells UC are arranged in the memory cell array Ar in the memory cell area M. In the unit memory cells UC, a selection gate transistor STD is provided on a side which is connected to bit lines BL₀ to BLₙ₋₁, and a selection gate transistor STS is provided on aside of a source line SL. There are m (for example, m=2^{k}) memory cell transistors MT₀ to MTₘ₋₁ connected in series between the selection gate transistors STD and STS. The memory cell transistors MT make up the memory cells MC.

The plurality of unit memory cells UC form memory cell blocks, and a plurality of the memory cell blocks form the memory cell array Ar. In other words, one block is formed of n columns of the unit memory cells UC arranged in parallel in a row direction (the X direction in FIG. 1). The memory cell array Ar is formed of a plurality of blocks arranged in the column direction (the Y direction in FIG. 1). Note that, in order to facilitate illustration, only one block is illustrated in FIG. 1.

Referring to one unit memory cell UC, a control line SGD is connected to the gate of the selection gate transistor STD which is connected to one of the bit lines BL₀ to BLₙ₋₁. A word line WLₘ₋₁ is connected to the control gate of the m-th memory cell transistor MTₘ₋₁. A word line WL₂ is connected to the control gate of the third memory cell transistor MT₂. A word line WL₁ is connected to the control gate of the second memory cell transistor MT₁. A word line WL₀ is connected to the control gate of the first memory cell transistor MT₀. A control line SGS is connected to the gate of the selection gate transistor STS which is connected to the source line SL. The bit lines BL₀ to BLₙ₋₁ are connected to a sense amplifier (not illustrated).

The selection gate transistors STD of the plurality of unit memory cells UC which are arranged in the row direction are electrically connected to the control line SGD by the gate electrodes thereof. Similarly, the selection gate transistors STS of the plurality of unit memory cells UC which are arranged in the row direction are electrically connected to the control line SGS by the gate electrodes thereof. The sources of the selection gate transistors STS are connected in common to the source line SL. The memory cell transistors MT₀ to MTₘ₋₁ of the plurality of unit memory cells UC which are arranged in the row direction are electrically connected to the word lines WL₀ to WLₘ₋₁, respectively, by the gate electrodes thereof.

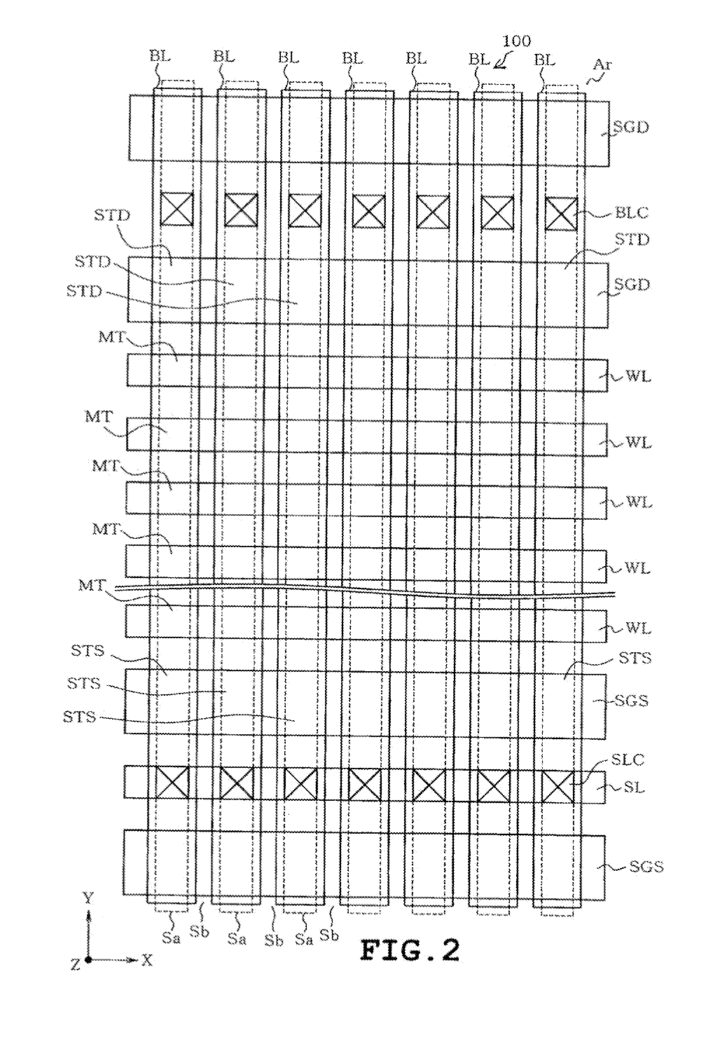

FIG. 2 is an example of a plan view which schematically illustrates the layout pattern of a portion of the memory cell area M. Note that, hereinafter, the individual bit lines BL₀ to BLₙ₋₁ will be referred to as the bit lines BL, the word lines WL₀ to WLₘ₋₁ as the word lines WL, and the memory cell transistors MT₀ to MTₘ₋₁ as the memory cell transistors MT.

In FIG. 2, the source line SL, the control line SGS, the word lines WL, and the control lines SGD are separated from one another in the Y direction, and are disposed in parallel extending in the X direction. The bit lines BL are separated from one another in the X direction by a predetermined interval, and are arranged in parallel extending in the Y direction.

Element isolation areas Sb are formed to extend in the Y direction in the drawings. The element isolation areas Sb have an STI (Shallow Trench Isolation) structure which is formed by filling a trench with an insulating film. A plurality of the element isolation areas Sb are formed at a predetermined interval in the X direction. Due to the element isolation areas Sb, a plurality of element areas Sa, which are formed on a surface layer portion of the semiconductor substrate to extend along the Y direction, are formed to be separated in the X direction. In other words, the element isolation areas Sb are provided between the element areas Sa, and the semiconductor substrate is divided into a plurality of element areas Sa by the element isolation areas Sb.

The word lines WL are formed to extend along a direction orthogonal to the element area Sa (the X direction in FIG. 2). A plurality of the word lines WL are formed in the Y direction in the drawings at a predetermined interval. The memory cell transistors MT are disposed at intersecting portions of the word lines WL and the element areas Sa. The plurality of memory cell transistors MT which are adjacent in the Y direction form a portion of a NAND column (a memory cell string). The memory cell transistors MT make up the memory cells MC.

The selection gate transistors STS and STD are disposed at the intersecting portions of the control lines SGS and SGD and the element areas Sa. The selection gate transistors STS and STD are provided to be adjacent to both outer-side memory cell transistors MT in the Y direction of the end portions of the NAND column.

A plurality of the selection gate transistors STS of the source line SL side are provided in the X direction, and the selection gates SG of the plurality of selection gate transistors STS are electrically connected by the control line SGS. The selection gates SG of the selection gate transistors STS are formed at the portions where the control line SGS and the element areas Sa intersect. Source line contacts SLC are provided at intersecting portions of the source line SL and the element areas Sa.

A plurality of the selection gate transistors STD are provided in the X direction in the drawings, and the selection gates SG of the selection gate transistors STD are electrically connected by the control line SGD. The selection gate transistors STD are formed at the portions where the control line SGD and the element areas Sa intersect. Bit line contacts BLC are formed on each of the element areas Sa between the adjacent selection gate transistors STD.

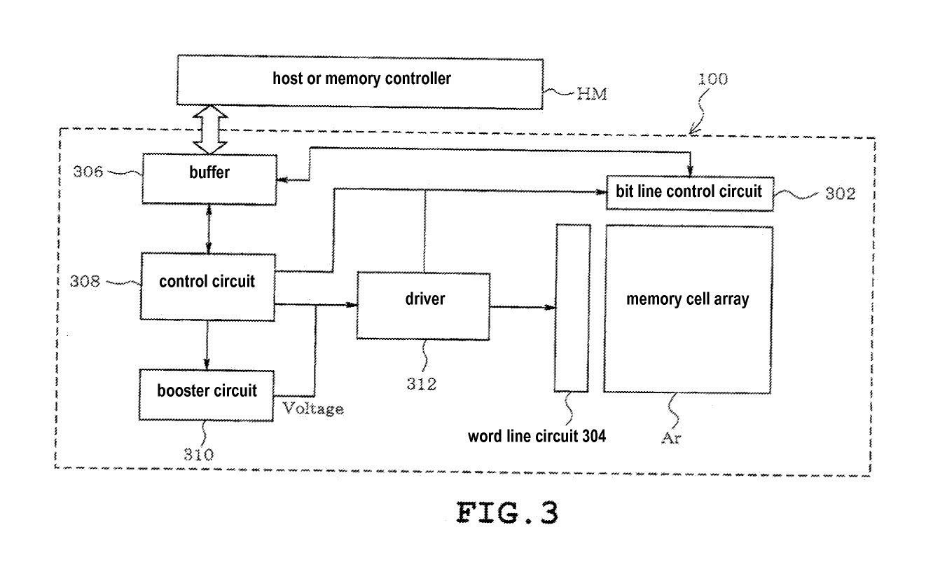

FIG. 3 is a block diagram illustrating an example of the configuration of the NAND flash memory including peripheral circuits. The NAND flash memory device 100 is provided with the memory cell array Ar, which is formed by disposing the memory cells MC which store data in a matrix. The memory cell array Ar includes the plurality of bit lines BL, the plurality of word lines WL, the source line SL, and the plurality of memory cells MC. In regard to the memory cells MC, n bits (where n is a natural number of 2 or greater) of data may be stored in one memory cell.

Various commands CMD, addresses ADD, and data DT which control the operation of the NAND flash memory and are supplied from a host or a memory controller HM, are input to a buffer 306. Write data which is input to the buffer 306 is supplied to the bit line BL which is selected by a bit line control circuit 302. In addition, the various commands CMD and addresses ADD are input to a control circuit 308, and the control circuit 308 controls a booster circuit 310, a driver 312 or the like based on the commands CMD and addresses ADD. In addition, control signals ALE (address latch enable), CLE (command latch enable), WE (write enable), and RW (read enable) are also input to the buffer 306. In addition, the control circuit 308 may control an output buffer circuit or the like disposed in the buffer 306.

According to the control of the control circuit 308, the booster circuit 310 generates the voltages which are necessary for writing, reading and erasing, and supplies the voltages to the driver 312. According to the control of the control circuit 308, the driver 312 supplies these voltages to the bit line control circuit 302 and a word line control circuit 304. According to these voltages, the bit line control circuit 302 and the word line control circuit 304 read data from the memory cells MC, write data to the memory cells MC, and perform erasure of the data of the memory cells MC.

The memory cell array Ar is connected to the bit line control circuit 302 for controlling the voltages of the bit lines BL, and the word line control circuit 304 for controlling the voltages of the word lines WL. In addition, the bit line control circuit 302 and the word line control circuit 304 are connected to the driver 312.

In other words, the driver 312 controls the bit line control circuit 302 based on the addresses ADD, and reads the data of the memory cells MC in the memory cell array Ar via the bit lines BL. In addition, the driver 312 controls the bit line control circuit 302 based on the addresses ADD, and writes to the memory cells MC in the memory cell array Ar via the bit lines BL.

In addition, there are cases in which the bit line control circuit 302, the word line control circuit 304, the driver 312, and the control circuit 308 are referred to collectively as the “control circuit”.

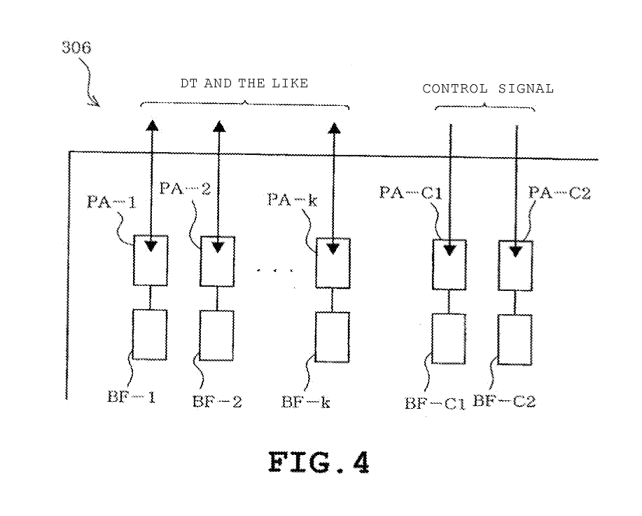

FIG. 4 is a block diagram illustrating an example of the buffer 306 of the NAND flash memory.

A plurality of pads PA are disposed in the buffer 306. Bonding wires, through hole vias and the like are connected to the pads PA. Via the bonding wires, through hole vias and the like, signals such as the data DT are input to the pads PA from the host or memory controller HM. Here, pads to which the data DT, the commands CMD, the addresses ADD and the like are input are pads PA-1 to k (where k is an integer of 1 or greater), and pads to which control signals such as the write enable signal and the chip enable signal are input are pads PA-C1 and C2. Note that, two or more of the pads PA-C1 and C2 may be provided.

Buffer units BF-1 to k are connected to the pads PA-1 to k, respectively. Buffer units BF-C1 and C2 are connected to the pads PA-C1 and C2, respectively.

Note that, pads to which a ground voltage VSS and an external voltage VEXT are supplied are also present in the NAND flash memory device 100. Here, in order to forma current path for allowing surges to escape, a protective element may be connected to the pads which supply the external voltage.

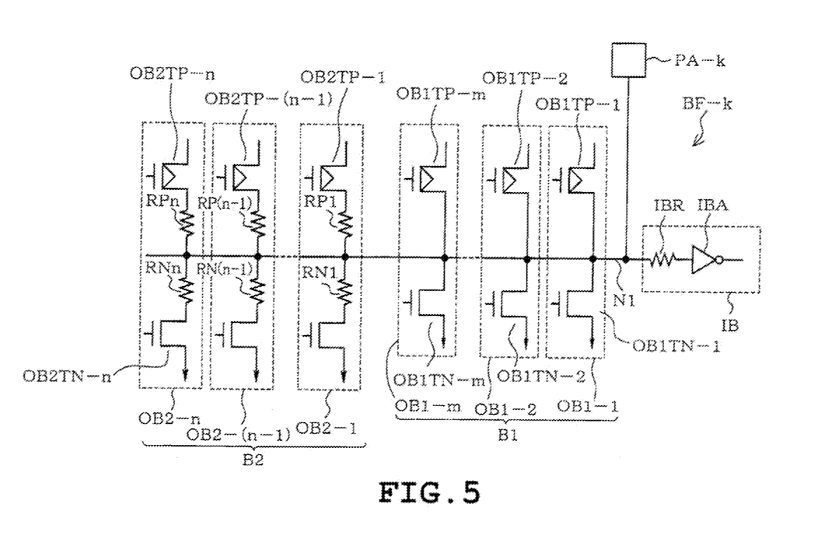

As illustrated in FIG. 5, a plurality of output buffer circuits OB1-1 to OB1-m (where m is an integer of 2 or greater) are disposed, and an output buffer circuit group B1 is configured. The output buffer circuits OB1-1 to OB1-m are connected in series to a node N1. Each of output buffer circuits OB1-1 to OB1-m includes p-type transistors OB1TP-1 to OB1TP-m and n-type transistors OB1TN-1 to OB1TN-m, respectively.

One end of each of the p-type transistors OB1TP-1 to OB1TP-m is connected to the node N1, and the other end is connected to the power supply voltage VEXT. One end of each of the n-type transistors OB1TN-1 to OB1TN-m is connected to the node N1, and the other end is connected to the ground voltage VSS. In addition, the control circuit 308 controls each of the gate electrodes (the control lines) of the p-type transistors OB1TP-1 to OB1TP-m and the n-type transistors OB1TN-1 to OB1TN-m, and may switch the p-type transistors OB1TP-1 to OB1TP-m and the n-type transistors OB1TN-1 to OB1TN-m between a conductive state and a non-conductive state.

Here, the p-type transistors OB1TP-1 to OB1TP-m may be said to be connected in parallel to the node N1, and the n-type transistors OB1TN-1 to OB1TN-m may be said to be connected in parallel to the node N1.

In addition, a plurality of output buffer circuits OB2-1 to OB2-n (where n is an integer of 2 or greater) are disposed, and an output buffer circuit group B2 is configured. The output buffer circuits OB2-1 to OB2-n are connected in series to the node N1. Each of output buffer circuits OB2-1 to OB2-n includes p-type transistors OB2TP-1 to OB2TP-n and n-type transistors OB2TN2 to OB2TN-n, respectively.

One end of each of the p-type transistors OB2TP-1 to OB2TP-n is connected to the power supply voltage VEXT. One end of each of the n-type transistors OB2TN2 to OB2TN-n is connected to the ground voltage VSS. The other ends of the p-type transistors OB2TP-1 to n of the output buffer circuits OB2-1 to OB2-n are connected to the node N1 via resistors RP1 to RPn, respectively. The other ends of the n-type transistors OB2TN-1 to n of the output buffer circuits OB2-1 to OB2-n are connected to the node N1 via resistors RN1 to RNn, respectively.

Here, the resistors RP1 to RPn and RN1 to RNn2, and R3 are, for example, wiring resistors. A wiring 42 of the ODT circuit unit described hereinafter may use, for example, the resistors RP1 to RPn, RN1 to RNn2, and R3 of the output buffer circuit as the wiring resistors.

In addition, the control circuit 308 controls each of the gate electrodes (the control lines) of the p-type transistors OB2TP-1 to OB2TP-n and the n-type transistors OB2TN2 to OB2TN-n, and may switch the p-type transistors OB2TP-1 to OB2TP-n and the n-type transistors OB2TN2 to OB2TN-n between a conductive state and a non-conductive state.

Here, the p-type transistors OB2TP-1 to OB2TP-n may be said to be connected in parallel to the node N1, and the n-type transistors OB2TN2 to OB2TN-n may be said to be connected in parallel to the node N1.

In addition, the p-type transistors OB1TP-1 to OB1TP-m and OB2TP-1 to OB2TP-n may be said to be connected in parallel to the node N1, and the n-type transistors OB1TN-1 to OB1TN-m and OB2TN-1 to OB1TN-n may be said to be connected in parallel to the node N1.

The above is the general configuration of the NAND flash memory device 100 to which the present embodiment is applied. The configuration is the same for the second embodiment described hereinafter.

The NAND flash memory may be divided largely into the memory cell unit and the peripheral circuit unit. In order to increase the memory capacity per unit area and to reduce the manufacturing cost per bit, the memory cells continue to be miniaturized. The distance between adjacent cells becomes smaller with the miniaturization of the memory cells; however, associated with this is an increase in the mutual interference of adjacent cells (this is referred to as adjacent cell interference). In the NAND flash memory, writing of data is performed in order a page at a time.

For example, a case is assumed in which data 0 is written to a cell in the writing of a certain page, and data 1 is written to a cell adjacent to the cell in the writing of the next page. There is a case in which, due to the electrical coupling of cells via the inter-cell insulating film of both, the potential of the cell to which the data 0 is written is pulled by the potential of the adjacent cell to which the data 1 is written and flips from the data 0 to 1. In this manner, the adjacent cell interference causes a degradation in reliability in the data retention property.

As one of countermeasures, a structure in which air gaps are provided between the word lines (known as the word line air gap structure) is proposed. In comparison to a structure where the space between word lines is filled with an insulating film such as a silicon oxide film, this structure may reduce the permittivity between the word lines. Accordingly, the wiring capacitance between the adjacent cells may be reduced, and the adjacent cell interference may be reduced.

Meanwhile, the air gap structure increases the difficulty of process integration. For example, in normal NAND flash memory, wiring layers are formed on the gate electrodes of the memory cells and the peripheral circuits. Of the wiring layers, as the material of the wiring layer which is disposed on the layer closest to the gate electrodes (for example, the source line SL), mainly metals such as tungsten (W) and aluminum (Al) are used, and is normally formed using a process common with the memory cells and the peripheral circuits. Here, there is a case in which the wiring layer which is disposed on the layer closest to the gate electrodes is referred to as the lowest wiring layer (the lowest wiring level).

The wiring which is formed on the lowest wiring layer is often formed using the so-called damascene process, and the depth of the wiring groove in the formation is controlled such that the wiring groove does not reach the air gaps. When the wiring groove is too deep and the wiring groove reaches the air gaps provided between the word lines, the metal for wiring formation which is subsequently stacked encroaches the inside of the air gaps, causing shorting or the like between the wiring and the gate electrodes of the cells. Therefore, for the wiring groove not to reach the air gaps even if variation in depth occurs, it is necessary to set the height of the bottom of the wiring groove so as to secure a fixed distance between the air gaps and the wiring groove.

Next, description will be given regarding the influence that variations in the resistance of the wiring has on the circuit and the necessity of reducing the variations. In recent years, an On Die Termination (ODT) circuit is implemented in the peripheral circuits of the NAND flash memory. The ODT circuit is a circuit which operates to match the impedance of the NAND flash memory with the impedance of an external circuit such as a controller. Accordingly, signal degradation due to a mismatch in impedance of both is suppressed.

The ODT circuit is configured of only MOSFETs (metal-oxide-semiconductor field-effect transistor) in the related art; however, in recent years a configuration in which MOSFETs and wiring resistors are combined is being proposed. While this is advantageous in comparison to a case in which the ODT circuit is formed using only MOSFETs in that the linearity of the current in relation to the voltage is good, the influence of the impedance due to the wiring resistor is received. Therefore, in order to obtain the desired impedance, there is a need to reduce the variation in the resistances of the wiring resistors which are used in the ODT circuit.

Here, as the wiring layer for the wiring resistor, any of the wiring layers, of which multiple layers are present in the NAND flash memory, may be used; however, there is a case in which a wiring which is formed on the lowest wiring layer is used from the perspective of having excellent EM (Electron Migration) resistance and a high resistance.

In addition, since tungsten is generally used for the wiring which is formed on the lowest wiring layer, the EM resistance is also excellent. In addition, the wiring which is formed on the lowest wiring layer often has the highest resistance, even among the wiring layers, of which multiple layers are present in the NAND flash memory. Therefore, the area of the wiring resistor may be reduced. For example, the ODT circuit may be used for the output buffer circuit described above.

As described above, in the NAND flash memory to which the word line air gap structure is applied, it is necessary to secure a fixed distance from the air gaps such that the wiring, which is formed on the lowest wiring layer which is formed on the air gaps, does not contact the air gaps between the word lines. In addition, in an area which is used as a portion of the ODT circuit, there is demand for the resistance variation of the wiring which is formed on the lowest wiring layer to be small.

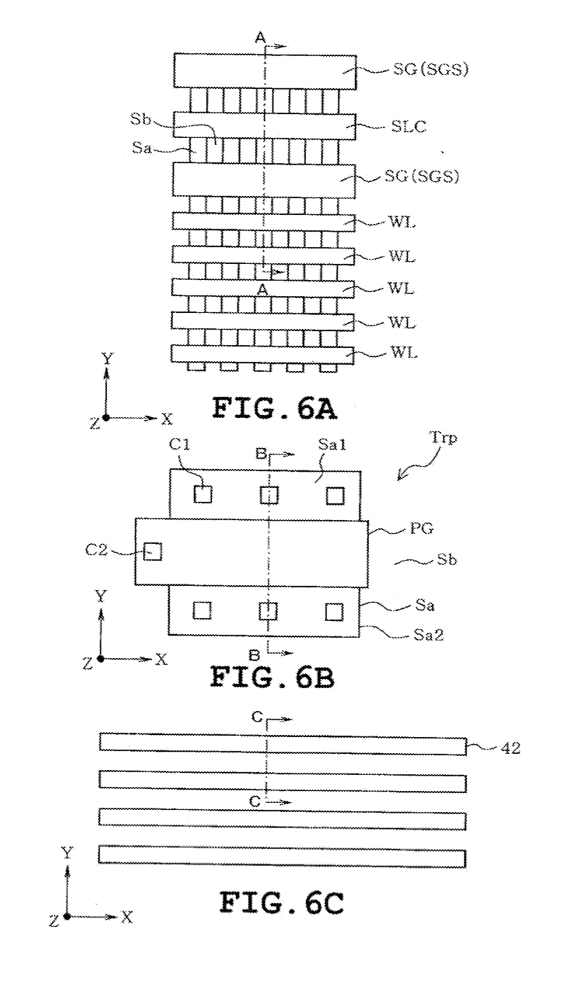

Next, description will be given of the configuration of the NAND flash memory device 100 according to the present embodiment with reference to FIGS. 6A, 6B, 6C to 17A, 17B, and 17C.

FIGS. 6A, 6B, and 6C illustrate examples of the layout of the memory cell area M of the NAND flash memory according to the present embodiment, a transistor Trp forming area and the ODT circuit unit of the peripheral circuit unit. Here, wirings 36, 40, and 42 which are described hereinafter are formed on the lowest wiring layer.

FIG. 6A is a layout diagram including a portion of the source line SL connection side, that is, the control line SGS side of the memory cell area M of the NAND flash memory device 100 according to the present embodiment. As illustrated in FIG. 6A, in the memory cell area M of the NAND flash memory device 100, the element area Sa and the element isolation area Sb of a line/space shape extending in the Y direction are formed in parallel, alternating in the X direction on a semiconductor substrate 12.

On the semiconductor substrate 12, the word lines WL are formed to intersect the element areas Sa and the element isolation areas Sb in a perpendicular direction (the X direction). The plurality of word lines WL extend in the X direction, and are lined up in parallel separated by a predetermined interval in the Y direction in the line/space shape. The two control lines SGS of the source line SL side are disposed parallel to the word lines WL, and the source line contact SLC is provided between the adjacent control lines SGS.

FIG. 6B is a plan view illustrating an example of the layout of the transistor Trp which is formed on the peripheral circuit unit of the NAND flash memory device 100 according to the present embodiment. As illustrated in FIG. 6B, the square shaped element area Sa is formed, and the element isolation area Sb is formed on the periphery of the element area Sa. A gate electrode PG of the transistor Trp crosses the central portion of the element area Sa, and divides the square shaped element area Sa into two areas, an element area Sa1, and an element area Sa2.

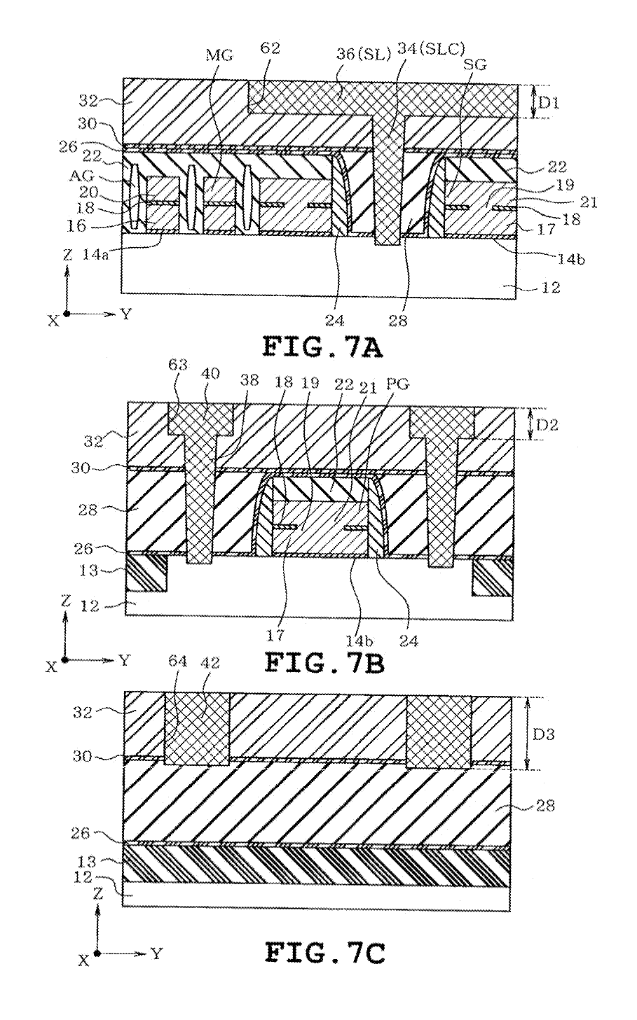

The element areas Sa1 and Sa2 are the source and drain areas of the transistor Trp. Contacts C1 are formed on the element areas Sa1 and Sa2. A contact C2 is formed on the gate electrode PG. In FIG. 6B, the wiring of the upper layers is omitted from the drawing; however, as illustrated in FIG. 7B hereinafter, the wiring 40 and the like is formed and connected on the upper layers.

FIG. 6C illustrates an example of the layout diagram of the wiring 42 of the ODT circuit unit. As illustrated in FIG. 6C, the plurality of wirings 42 extend in the X direction in the drawing (the left and right directions), and are lined up in parallel separated by a predetermined interval in the Y direction in the line/space shape. The wirings 42 of the ODT circuit unit may be used as the wiring resistors for the resistors RP1 to RPn, RN1 to RNn2, and R3 of the output buffer circuits OB2-1 to OB2-n, and OB2-1 to OB2-n described above, for example.

FIG. 7A is an example of a diagram illustrating the cross-sectional structure of the memory cell area M of the NAND flash memory device 100, and exemplifies a vertical cross-sectional view across the A-A line of FIG. 6A. As illustrated in FIG. 7A, a tunnel film 14a and the gate oxide film 14b are formed on the semiconductor substrate 12. A silicon substrate may be used as the semiconductor substrate 12, for example. A memory gate MG which is a gate electrode of the memory cell transistor MT, and a selection gate SG which is a gate electrode of the selection gate transistor STS are formed above the semiconductor substrate 12.

The tunnel film 14a is provided between the memory gate MG and the semiconductor substrate 12. The gate oxide film 14b is provided between the selection gate SG and the semiconductor substrate 12. A silicon oxide film may be used, for example, as the tunnel film 14a and the gate oxide film 14b.

The memory gate MG includes a charge storage layer 16, an insulating film 18, and a control gate 20, which are stacked. In the memory gate MG, the charge storage layer 16 and the control gate 20 are isolated using the insulating film 18. The selection gate SG includes a lower electrode 17, the insulating film 18, and an upper electrode 21 which are stacked.

In the selection gate SG, an opening portion 19 is provided in the center portion of the insulating film 18. Therefore, the lower electrode 17 and the upper electrode 21 are electrically connected, and function as a single, integrated, gate electrode. The upper portions of the memory gate MG and the selection gate SG, the space between adjacent memory gates MG, and the space between the memory gate MG and the selection gate SG are covered by an interlayer insulating film 22. A silicon oxide film may be used, for example, as the interlayer insulating film 22.

Air gaps AG are formed between the adjacent memory gates MG, and between the memory gate MG and the selection gate SG. Providing the air gaps AG enables a reduction in the wiring capacitance between the memory gates MG, and between the memory gate MG and the selection gate SG, and it is possible to reduce the adjacent cell interference. The upper surface of the interlayer insulating film 22 is planarized, and a liner film 26 is provided on the upper portion thereof.

Between the adjacent selection gates SG, a side wall insulating film 24 is provided on the side surface of the selection gate SG, and the liner film 26 and the interlayer insulating film 28 are provided on the semiconductor substrate 12. A silicon nitride film may be used, for example, as the liner film 26. The liner film 26 protects the memory cell area M from impurities and hydrogen during the formation of the upper layer wiring, and serves the role of an etching process stopper for adjusting the depth of the contacts in the formation of the contacts (the source line contact SLC and the like). A silicon oxide film may be used, for example, as the interlayer insulating film 28.

The upper surface of the interlayer insulating film 28 is planarized, and the upper surface thereof may be positioned at substantially the same height as the upper surface of the liner film 26. A barrier film 30 is provided on the upper surface of the interlayer insulating film 28, and an interlayer insulating film 32 is provided further above the barrier film 30. A silicon nitride film may be used, for example, as the barrier film 30. The barrier film 30 also includes the role of blocking impurities and hydrogen during the formation of the upper layer wiring. A silicon oxide film may be used, for example, as the interlayer insulating film 32.

Between adjacent selection gates SG, a contact plug 34 (the source line contact SLC) is formed so as to penetrate from the surface of the interlayer insulating film 32 to the surface of the semiconductor substrate 12, and wiring 36 (the source line SL) is provided on the contact plug 34.

Note that, the wiring 36 is formed using the so-called damascene process, and is formed by filling the inside of a wiring groove 62 which is provided in the interlayer insulating film 32 with a metal film. Here, the lower surface of the wiring 36 (the source line SL) does not contact the barrier film 30, and they are separated in the Z direction in the drawing (the up and down directions). The lower surface of the wiring 36 is present in a higher position than the height of the surface of the barrier film 30.

The contact plug 34 and the wiring 36 are formed of a stacked film of a barrier metal and a metal film, for example. Titanium nitride (TiN) may be used, for example, as the barrier metal, and tungsten may be used, for example, as the metal film.

FIG. 7B is an example of a diagram illustrating the cross-sectional structure of the transistor Trp of the peripheral circuit unit, and exemplifies a vertical cross-section across the B-B line of FIG. 6B. As illustrated in FIG. 7B, an element isolation insulating film 13 and the gate oxide film 14b are formed on the semiconductor substrate 12. The gate electrode PG of the transistor Trp is formed above the semiconductor substrate 12. The gate electrode PG has the same structure as the selection gate SG. The side wall insulating film 24 is provided on the side surface of the gate electrode PG.

The liner film 26 is formed on the upper portion of the semiconductor substrate 12, the upper portion of the gate electrode PG, and the surface of the side wall insulating film 24. The interlayer insulating film 28 is provided on the liner film 26 on the semiconductor substrate 12. The upper surface of the interlayer insulating film 28 is planarized, and is positioned at substantially the same height as the upper surface of the gate electrode PG. The barrier film 30 is provided on the upper portion, and the interlayer insulating film 32 is provided further above the barrier film 30.

Contact plugs 38 are provided on both sides of the gate electrode PG so as to penetrate from the surface of the interlayer insulating film 32 to the surface of the semiconductor substrate 12, and the wiring 40 is formed on the contact plugs 38. The wiring 40 is formed using the so-called damascene process, and is formed by filling the inside of a wiring groove 63 which is provided in the interlayer insulating film 32 with a metal film. Here, the lower surface of the wiring 40 does not contact the barrier film 30, and they are separated in the Y direction in the drawing. The lower surface of the wiring 40 is present in a higher position than the height of the surface of the barrier film 30.

FIG. 7C is an example of a diagram illustrating a portion of the cross-sectional structure of the ODT circuit unit of the peripheral circuit unit, and exemplifies a vertical cross-section across the C-C line of FIG. 6C. As illustrated in FIG. 7C, an element isolation insulating film 13 is formed on the semiconductor substrate 12, and the liner film 26 is formed thereon. The interlayer insulating film 28, the barrier film 30, and the interlayer insulating film 32 are provided on the liner film 26.

The wiring 42 is provided to penetrate from the surface of the interlayer insulating film 32 to the barrier film 30. The wiring 42 is formed using the so-called damascene process, and is formed by filling the inside of a wiring groove 64 which is provided in the interlayer insulating film 32 with a metal film.

The lower surface of the wiring 42 (the wiring groove 64) is positioned below, lower than the height of the lower surface of the barrier film 30. The position of the lower surface of the wiring 42 (the wiring groove 64) may match the position of the lower surface of the barrier film 30. The side surface of the wiring 42 (the wiring groove 64) contacts the barrier film 30.

The liner film 26 is formed between the side wall insulating film 24 and the selection gate SG, or on the semiconductor substrate 12 of the peripheral circuit unit. Conversely, the barrier film 30 is formed after the interlayer insulating film 28 is formed between the selection gates SG and on the peripheral circuit unit. Therefore, the barrier film 30 becomes substantially the same height in the peripheral circuit unit regardless of the presence or absence of the gate electrodes of the lower layer. In other words, in the transistor portion of the peripheral circuit unit and the ODT circuit unit, the height of the barrier film 30 (the height position in the Z direction, the height position in the up and down directions) is substantially the same.

Furthermore, the distance from the surface of the semiconductor substrate 12 to the barrier film 30 is substantially equal to the distance from the surface of the semiconductor substrate 12 to the barrier film 30. In addition, the distance from the surface of the semiconductor substrate 12 to the lower surface of the source line 36 is larger than the distance from the surface of the semiconductor substrate 12 to the lower surface of the wiring 42. In addition, the distance from the surface of the semiconductor substrate 12 to the upper surface of the source line 36 is equal to the distance from the surface of the semiconductor substrate 12 to the upper surface of the wirings 40 and 42.

As illustrated in FIG. 7C, the depth or a film thickness (in other words, the depth of the wiring groove 64) D3 of the wiring 42 of the ODT circuit unit is larger than the depth or a film thickness (in other words, the depth of the wiring groove 62) D1 of the wiring 36 in the memory cell area M illustrated in FIG. 7A. In other words, the depth D3 of the wiring groove 64 is deeper than the depth D1 of the wiring groove 62.

Within the peripheral circuit unit, a depth D2 of the wiring 40 (the wiring groove 62) outside of the wiring portions of the ODT circuit unit, for example, in the transistor Trp forming area illustrated in FIG. 7B, need not necessarily be deeper than the depth D1 of the wiring 36 (the wiring groove 62) in the memory cell area M. In the transistor Trp forming area illustrated in FIG. 7B, the distance between the wiring and the electrodes being separated is favorable for reducing the capacitance between the wiring and the gate electrodes. Therefore, it is desirable to deepen only the wiring 42 (the wiring groove 64) of the ODT circuit in the peripheral circuit unit.

Next, description will be given of the manufacturing method of the NAND flash memory device 100 according to the present embodiment, with reference to FIGS. 7A, 7B, and 7C to FIGS. 17A, 17B, and 17C. FIGS. 7A, 7B, and 7C to FIGS. 17A, 17B, and 17C are examples of diagrams for illustrating the manufacturing method of the NAND flash memory device 100 of the present embodiment, and illustrate the states of each process in the manufacturing processes.

The planar layout of the NAND flash memory device 100 according to the present embodiment is the same as the planar views illustrated in FIGS. 6A, 6B, and 6C. FIGS. 7A to 17A illustrate the vertical cross-sectional view across the A-A line of FIG. 6A. FIGS. 7B to 17B illustrate the vertical cross-sectional view across the B-B line of FIG. 6B. FIGS. 7C to 17C illustrate the vertical cross-sectional view across the C-C line of FIG. 6C.

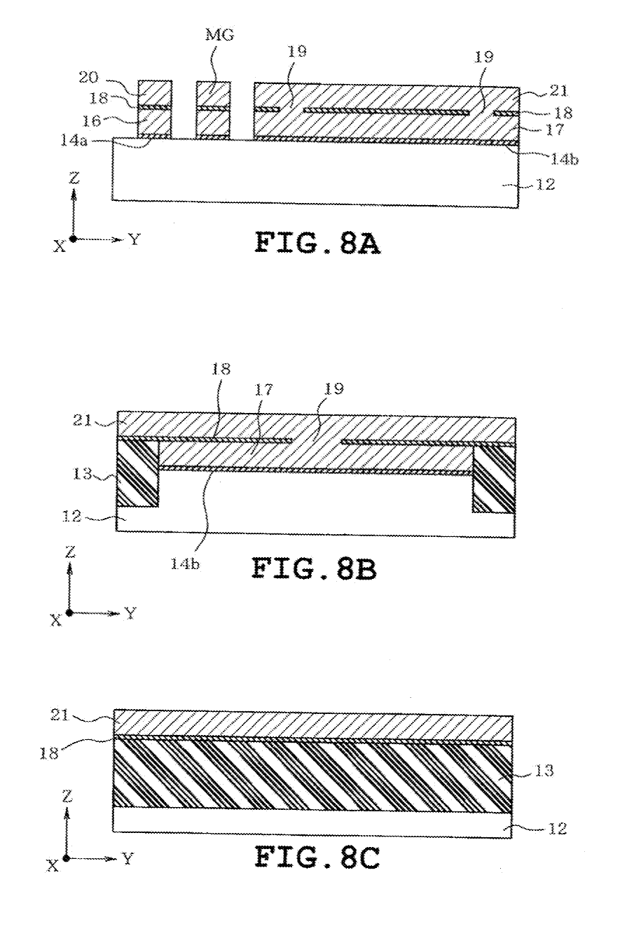

FIGS. 8A, 8B and 8C illustrate a state in which the processing of the memory gate MG of the memory cell area M is completed. After forming the element isolation insulating film 13 on the semiconductor substrate 12, the tunnel film 14a and the gate oxide film 14b are formed, and on the upper portion thereof, the charge storage layer 16, the insulating film 18, the control gate 20, the lower electrode 17, and the upper electrode 21 are formed. The tunnel film 14a and the gate oxide film 14b are formed of a silicon oxide film, for example. The silicon oxide film may be formed using a thermal oxidation method, for example.

The charge storage layer 16 and the lower electrode 17 are formed in the same process, and amorphous silicon may be used, for example. The amorphous silicon may be formed using a CVD method, for example. The insulating film 18 is formed of an ONO (Oxide Nitride Oxide) film, which is a stacked film of silicon oxide film/silicon nitride film/silicon oxide film, for example. The ONO film may be formed using the CVD method, for example.

The control gate 20 and the upper electrode 21 are formed in the same process, and a stacked structure of amorphous silicon and a metal film may be used, for example. Tungsten may be used as the metal film, for example. The tungsten may be formed using a sputtering method, for example. In the area where the selection gate SG is subsequently formed, the opening portion 19 is formed in the insulating film 18, and the lower electrode 17 and the upper electrode 21 are electrically connected at this portion.

In the stacked film of the charge storage layer 16, the insulating film 18, and the upper electrode 21, the memory gate MG and the space between the memory gate MG and the selection gate SG are processes using lithography or an RIE (Reactive Ion Etching) method. In the transistor Trp forming area illustrated in FIG. 8B, and the ODT circuit unit illustrated in FIG. 8C of the peripheral circuit unit, the element isolation insulating film 13, the insulating film 18, and the upper electrode 21 are formed to be stacked on the semiconductor substrate 12. At this stage, the selection gate SG illustrated in FIG. 8A, and the peripheral circuit unit illustrated in FIGS. 8B and 8C have not been yet processed.

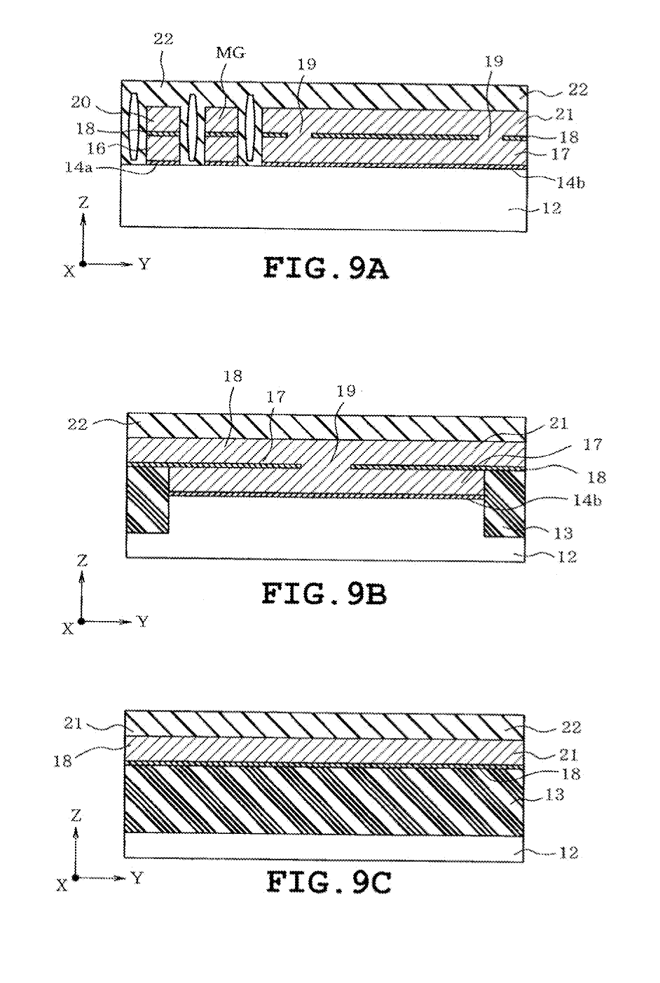

Next, as illustrated in FIGS. 9A, 9B and 9C, the interlayer insulating film 22 is formed. A silicon oxide film may be used, for example, as the interlayer insulating film 22. The air gaps AG are formed between the memory gates MG by forming the interlayer insulating film 22 in poor coverage conditions. In the memory cell area M illustrated in FIG. 8A, in the upper portion between the memory gates MG where the patterning is formed densely, the silicon oxide film is blocked and the air gaps AG are formed. In the peripheral circuit unit illustrated in FIGS. 8B and 8C, the air gaps AG are not formed since the space between the gate electrodes is wide.

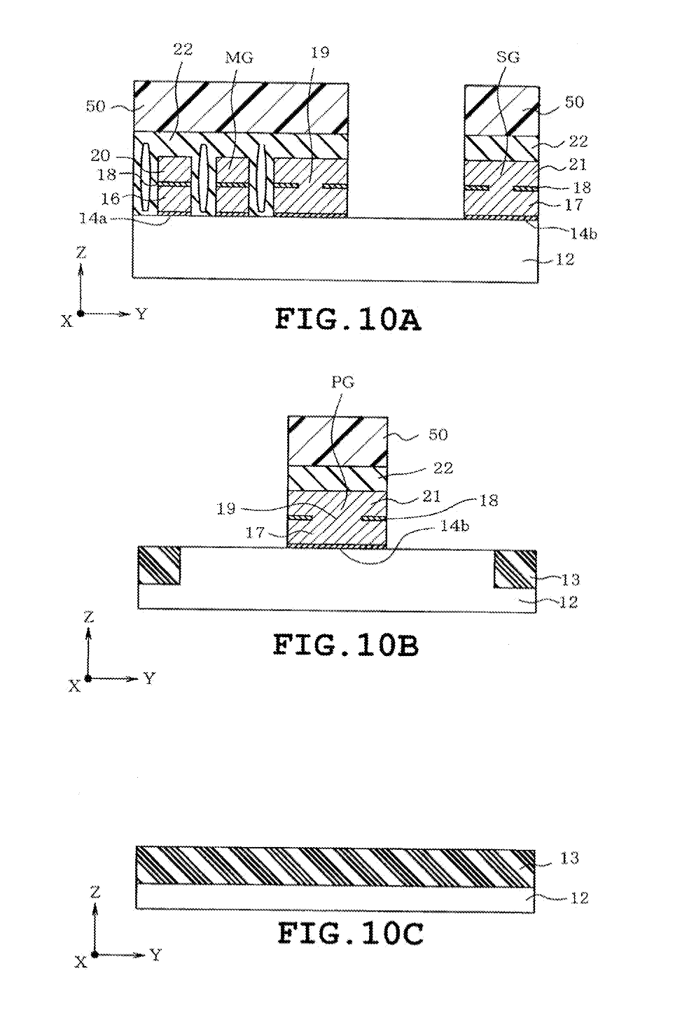

Next, as illustrated in FIGS. 10A, 10B and 10C, a resist 50 is formed using lithography, and the selection gate SG and the gate electrode PG are processed using the RIE method with the resist 50 as a mask. At this time, in the ODT circuit unit illustrated in FIG. 10C, since the resist 50 has not been yet formed, the interlayer insulating film 22, the upper electrode 21 and the insulating film 18 are removed in relation to the entire surface of the area using etching, and the upper surface of the element isolation insulating film 13 is exposed.

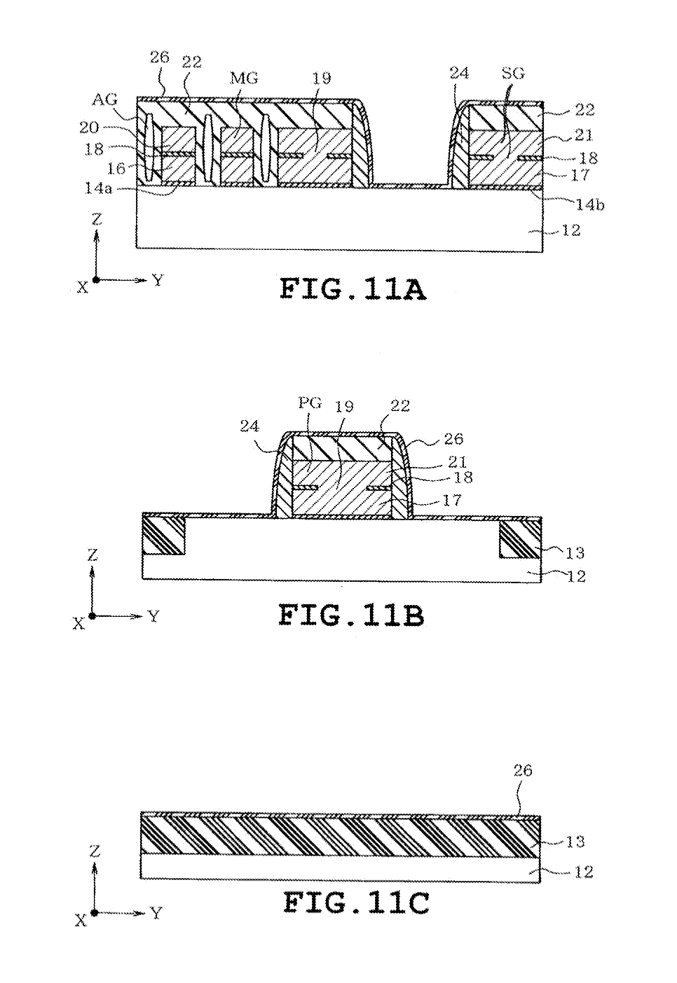

Next, as illustrated in FIGS. 11A, 11B, and 11C, the side wall insulating film 24 is formed on the side walls of the selection gate SG and the gate electrode PG. A silicon oxide film may be used, for example, as the side wall insulating film 24. Next, the liner film 26 is formed on the semiconductor substrate 12, the memory gate MG, the gate electrode PG, and the surface of the element isolation insulating film 13. A silicon nitride film may be used, for example, as the liner film 26. The silicon nitride film may be formed using the CVD method, for example.

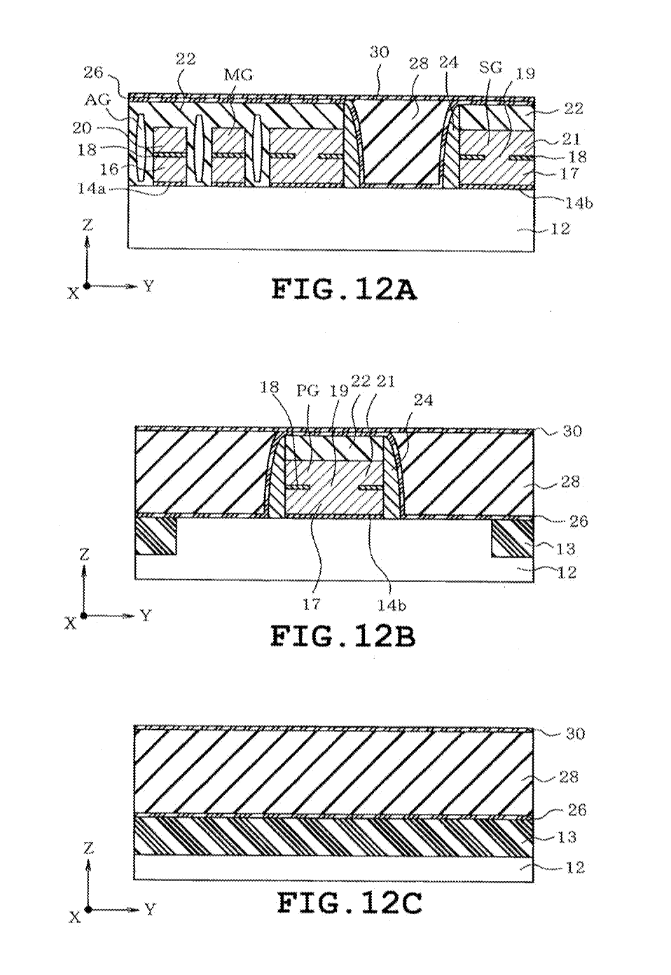

Next, as illustrated in FIGS. 12A, 12B and 12C, the interlayer insulating film 28 is formed; and next, the upper surface is planarized using the CMP (Chemical Mechanical Polishing) method. In the polishing process using the CMP method, the polishing may be stopped at the height of the upper surface of the liner film 26 by using the liner film 26 as a polishing stopper. A silicon oxide film such as dTEOS (Densified Tetra Ethyl Ortho Silicate) or BSG (Boron-Silicate Glass) may be used, for example, as the interlayer insulating film 28.

Next, the barrier film 30 is formed. A silicon nitride film may be used, for example, as the barrier film 30. The silicon nitride film may be formed using the CVD method, for example. Here, a film of the same material as the liner film 26 is formed as the barrier film 30. In the present embodiment, silicon nitride films are used for both.

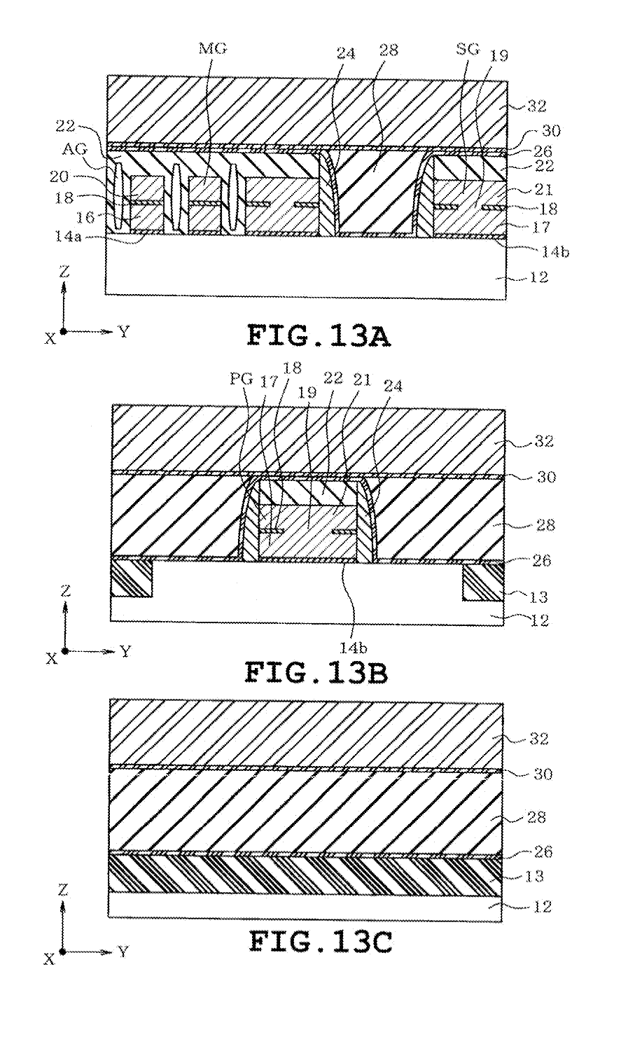

Next, as illustrated in FIGS. 13A, 13B and 13C, the interlayer insulating film 32 is formed on the barrier film 30. A silicon oxide film such as dTEOS or BSG may be used, for example, as the interlayer insulating film 32. After forming the film, the upper surface of the interlayer insulating film 32 is planarized using CMP, for example. The upper surface of the interlayer insulating film 32 is planarized in order to secure a sufficient resolution in the lithography used in the subsequent formation of the contacts and grooves.

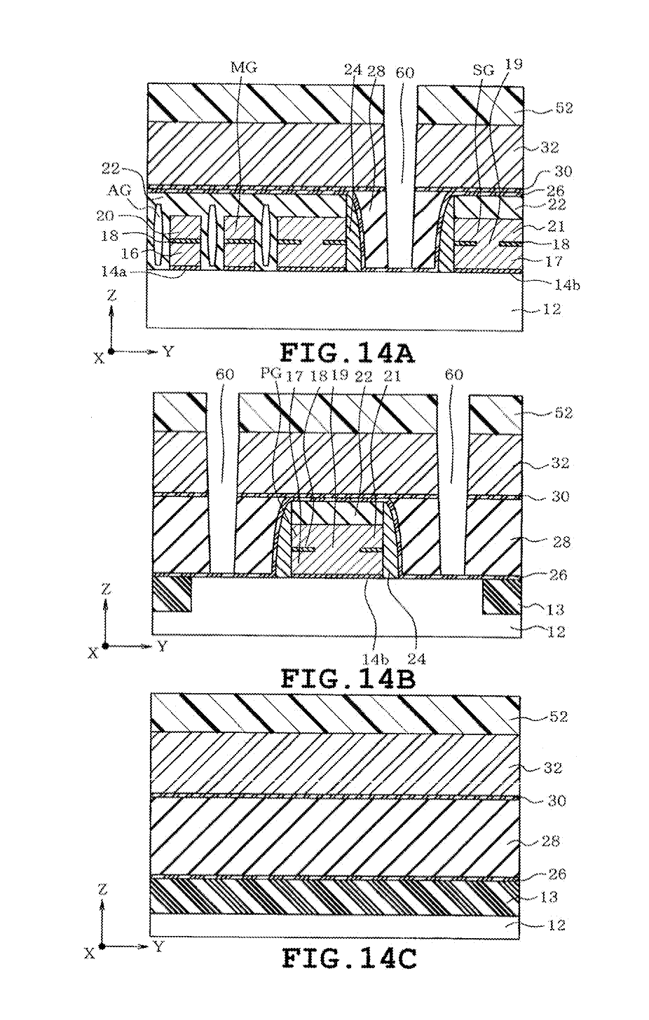

Next, as illustrated in FIGS. 14A, 14B and 14C, a resist 52 is formed using lithography; and next, contact holes 60 are formed using the RIE method with the resist 52 as a mask. The contact holes 60 are formed by etching the interlayer insulating film 32, the barrier film 30, and the interlayer insulating film 28.

In the etching step of the interlayer insulating film 28, the etching is performed under conditions of a high selection ratio between the silicon oxide film of the interlayer insulating film 28 and the silicon nitride film of the liner film 26, and is performed so as to stop on the liner film 26. In the ODT circuit unit illustrated in FIG. 14C, in this process, the resist 52 covers the entire surface of the upper surface, and the contact holes 60 are not formed.

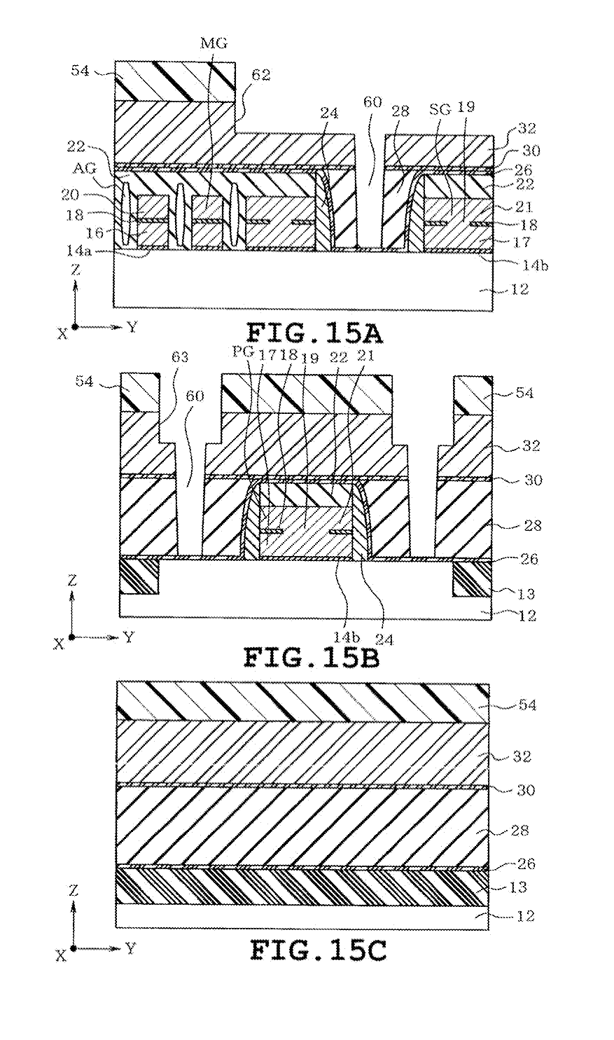

Next, as illustrated in FIGS. 15A, 15B and 15C, a resist 54 is patterned using lithography; and next, the wiring groove 62 is formed using the RIE method with the resist 54 as a mask. The wiring groove 62 is formed by etching the interlayer insulating film 32 to a predetermined depth thereof using the RIE method. In the present embodiment, the wiring grooves 62 and 63 are formed in the memory cell area M illustrated in FIG. 15A and the transistor Trp forming area illustrated in FIG. 15B of the peripheral circuit unit, respectively, and not formed in the ODT circuit unit of the peripheral circuit unit illustrated in FIG. 15C. In other words, the wiring groove 63 of the peripheral circuit unit is formed except for in the memory cell area M and the ODT circuit.

The entire surface of the upper surface of the ODT circuit unit illustrated in FIG. 15C is covered by the resist 54, and is not subjected to processing using the RIE method. In the etching step of the interlayer insulating film 32, the etching is performed under conditions of a high selection ratio between the silicon oxide film of the interlayer insulating film 32 and the silicon nitride film of the liner film 26, and is performed so as to stop on the liner film 26. Accordingly, since the liner film 26 is not removed from the lower surface of the contact holes 60, the semiconductor substrate 10 may be prevented from being exposed.

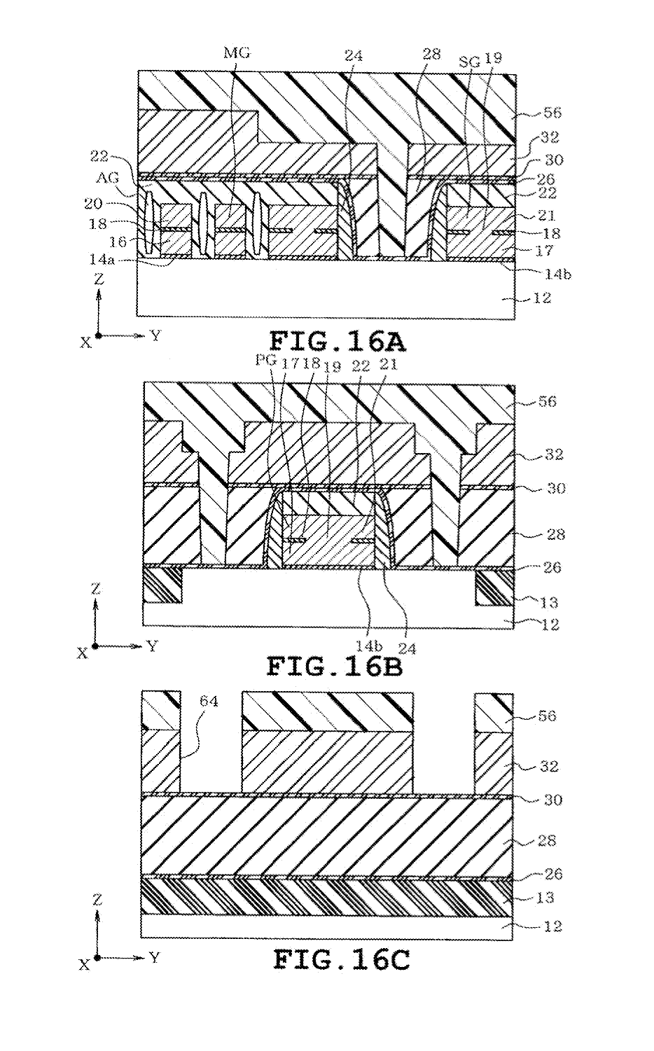

Next, as illustrated in FIGS. 16A, 16B and 16C, after peeling off the resist 54, a resist 56 is patterned using lithography; and next, the wiring groove 64 is formed using the RIE method with the resist 56 as a mask. The wiring groove 64 may be formed by removing the interlayer insulating film 32 using etching using the RIE method, and may be stopped at the upper surface of the barrier film 30. In the present embodiment, the wiring groove 64 is formed in the ODT circuit unit of the peripheral circuit unit illustrated in FIG. 16C without being formed in the memory cell area M illustrated in FIG. 16A and the transistor Trp forming area illustrated in FIG. 16B of the peripheral circuit unit. In other words, the wiring groove 64 of the ODT circuit unit is formed.

In the etching step of the interlayer insulating film 32, the etching is performed under conditions of a high selection ratio between the silicon oxide film of the interlayer insulating film 32 and the silicon nitride film of the barrier film 30, and is performed so as to stop on the barrier film 30. Accordingly, since the lower surface of the wiring groove 64 is substantially matched with the height of the upper surface of the barrier film 30, the variation in the depth of the wiring groove 64 may be reduced.

The memory cell area M and upper surface of the transistor Trp forming area illustrated in FIGS. 16A and 16B are covered by the resist 56, and are not subjected to processing using the RIE method.

Note that, the order of the process illustrated in FIGS. 15A, 15B and 15C, that is, the process of forming the wiring grooves 62 and 63, and the process illustrated in FIGS. 16A, 16B, and 16C, that is, the process of forming the wiring groove 64 (the process of forming the wiring groove 64 to the top of the barrier film 30) may be switched. In other words, after forming the wiring groove 64 of the ODT circuit unit, the wiring groove 62 of the memory cell area M and the transistor Trp forming area may be formed.

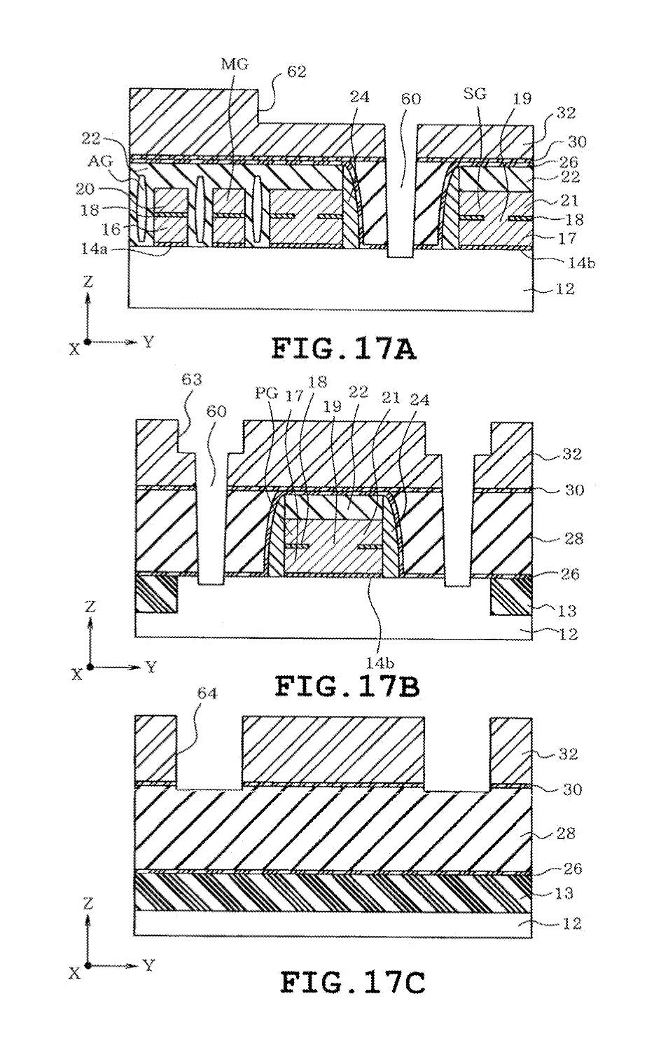

Next, as illustrated in FIGS. 17A, 17B, and 17C, after peeling off the resist 56, etching is performed using the RIE method, the liner film 26 (a silicon nitride film in the present embodiment) of the lower surfaces of the contact holes 60 is removed, and the surface of the semiconductor substrate 12 is exposed. At this time, the barrier film 30 (a silicon nitride film in the present embodiment) of the lower surface of the wiring groove 64 of the ODT circuit unit is removed by etching at the same time. In addition, a rut (a concave portion) may be formed in the surface of the semiconductor substrate 12 of the lower portion of the contact holes 60 by over etching in the etching. In addition, a rut (a concave portion) may be formed in the surface of the interlayer insulating film 28 of the lower portion of the wiring groove 64 of the ODT circuit unit by over etching in the etching. After undergoing this process, the final groove depths of the wiring groove 62 and the wiring groove 64 are determined.

Next, as illustrated in FIGS. 7A, 7B, and 7C, the inside of the contact holes 60, and the inside of the wiring grooves 62 and 64 are filled by forming a metal film such as tungsten (W) on the entire surface of the semiconductor substrate 12 using the CVD method or the like. Next, the surface of the interlayer insulating film 32 is exposed by removing, by polishing, the stacked metal using the CMP method, and the contact plugs 34 and 38 and the wirings 36, 40 and 42 are formed. In other words, the contact plugs 34 and 38, and the wirings 36, 40 and 42 are formed using the so-called damascene process.

As described above, the contact plug 34 and the wiring 36, and the contact plug 38 and the wiring 40 are formed integrally. In addition, the metal film may be a stacked film of titanium nitride and tungsten. In this case, the titanium nitride functions as a barrier metal film.

In the above processes, the NAND flash memory device 100 according to the present embodiment is formed. According to the present embodiment, since the variation in the thickness of the wiring 42 may be reduced, the variation in the resistances of the wiring resistors which are formed by the wiring 42 in the peripheral circuit unit may be reduced. In addition, since the wiring 40 depth may be formed shallower than the wiring 42 depth, a large distance may be secured between the lower surface of the wiring 40 and the air gaps AG in the memory cell area M.

Next, description will be given of, within the peripheral circuit unit, the connection state between the transistor Trp forming area illustrated in FIG. 7B and the ODT circuit unit illustrated in FIG. 7C. FIGS. 28 and 29 are examples of diagrams schematically illustrating the configuration in which the transistor Trp forming area and the ODT circuit unit of the peripheral circuit unit are connected.

FIG. 28 illustrates an example of a planar layout view, and FIG. 29 illustrates an example of a vertical cross-sectional view across the 29-29 line of FIG. 28. Note that, the same reference numerals are applied to elements provided with the same functions and configurations as in the embodiment described above, and description thereof will be omitted.

As described above, the depth (the film thickness) of the wiring 40 of the transistor Trp forming area and the depth (the film thickness) of the wiring 42 of the ODT circuit unit differ. Therefore, in a layout where both are simply connected, an area of the interlayer insulating film 32 at the seams which is subjected to etching twice is formed; thus, a groove may be formed on these portions. Thus, as illustrated in FIGS. 28 and 29, a connecting contact 80 is disposed on the upper portion of the wiring 40 of the transistor Trp forming area and the wiring 42 of the ODT circuit unit. By providing a wiring 82 which interconnects these on the upper portion of the contact 80, the transistor Trp forming area and the ODT circuit unit may be connected.

Here, the electrical capacitance of the ODT circuit is calculated as the pin capacitance, and when the capacitance is large, the operation speed decreases. Thus, the gate electrode is not disposed below the wiring 42. In addition, by disposing the element isolation insulating film 13 below the wiring 42, the distance between the wiring 42 and the semiconductor substrate 12 is increased. As a result, the wiring capacitance of the wiring 4 may be decreased.

### Second Embodiment

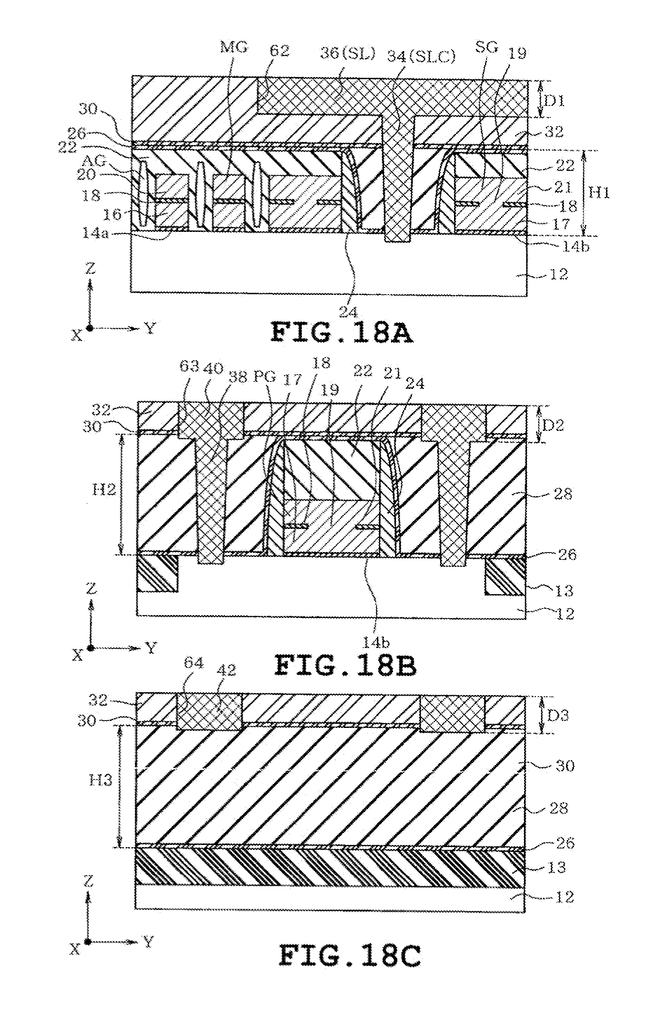

Hereinafter, description will be given of the NAND flash memory device as the semiconductor memory device to which the second embodiment is applied, with reference to FIGS. 18A, 18B, and 18C to FIGS. 27A, 27B, and 27C. In the description hereinafter, description will be given of matters which are common with the first embodiment using the drawings and the like which are used in the first embodiment. In addition, the same reference numerals are applied to elements provided with the same function and configuration as in the first embodiment, and description thereof will be omitted.

The layout of the memory cell area M, the transistor Trp forming area and the ODT circuit unit of the peripheral circuit unit of the NAND flash memory device 100 according to the second embodiment is the same as the configuration illustrated in FIGS. 6A, 6B, and 6C described in the first embodiment. The cross-sectional structure of the NAND flash memory device 100 according to the second embodiment differs from that according to the first embodiment.

Here, the distance from the surface of the semiconductor substrate 12 to the lower surface of the barrier film 30 is smaller than the distance from the surface of the semiconductor substrate 12 to the lower surface of the barrier film 30. In addition, the distance from the surface of the semiconductor substrate 12 to the lower surface of the wiring 40 is substantially equal to the distance from the surface of the semiconductor substrate 12 to the lower surface of the wiring 42.

FIGS. 18A, 18B, and 18C illustrate the cross-sectional structure of the NAND flash memory device 100 according to the second embodiment. FIG. 18A is an example of a diagram illustrating the cross-sectional structure of the memory cell area M of th NAND flash memory device 100, and exemplifies a vertical cross-section across the A-A line of FIG. 6A. FIG. 18B is an example of a diagram illustrating the cross-sectional structure of the transistor portion of the peripheral circuit area, and exemplifies a vertical cross-sectional view across the B-B line of FIG. 6B. FIG. 18C is an example of a diagram illustrating a portion of the cross-sectional structure of the ODT circuit unit, and exemplifies a vertical cross-sectional view across the C-C line of FIG. 6C.

In the second embodiment, the wiring 42 of the ODT circuit unit contacts the barrier film 30 in the same manner as in the first embodiment. However, as illustrated in FIG. 18C, the depth or the film thickness (the depth of the wiring groove 64) D3 of the wiring 42 is substantially equal to the depth or the film thickness (the depth of the wiring grooves 62 and 63) D1 and D2 of the wirings 36 and 40 in the memory cell area M and the transistor Trp forming area illustrated in FIGS. 18A and 18B.

In addition, the height H1 from the surface of the semiconductor substrate 12 in the memory cell area M illustrated in FIG. 18A to the lower surface of the barrier film 30 differs from the heights H2 and H3 from the surface of the semiconductor substrate 12 in the peripheral circuit unit (including the ODT circuit unit) illustrated in FIGS. 18B and 18C to the lower surface of the barrier film 30. The heights H2 and H3 of the barrier film 30 of the peripheral circuit unit (including the ODT circuit unit) are higher than the height H1 of the barrier film 30 in the memory cell area M. In other words, the height H1 of the barrier film 30 in the memory cell area M is smaller than the heights H2 and H3 of the barrier film 30 in the peripheral circuit unit. The other configurations are substantially the same as the configurations in the first embodiment.

Next, description will be given of the manufacturing method of the NAND flash memory device 100 according to the present embodiment, with reference to FIGS. 18A, 18B, and 18C to FIGS. 27A, 27B, and 27C. FIGS. 1A, 18B, and 18C to FIGS. 27A, 27B, and 27C are examples of diagrams for illustrating the manufacturing method of the NAND flash memory device 100 of the present embodiment, and illustrate the states of each process in the manufacturing processes.

FIGS. 18A to 27A illustrate the vertical cross-sectional view across the A-A line of FIG. 6A. FIGS. 18B to 27B illustrate the vertical cross-sectional view across the B-B line of FIG. 6B. FIGS. 18C to 27C illustrate the vertical cross-sectional view across the C-C line of FIG. 6C.

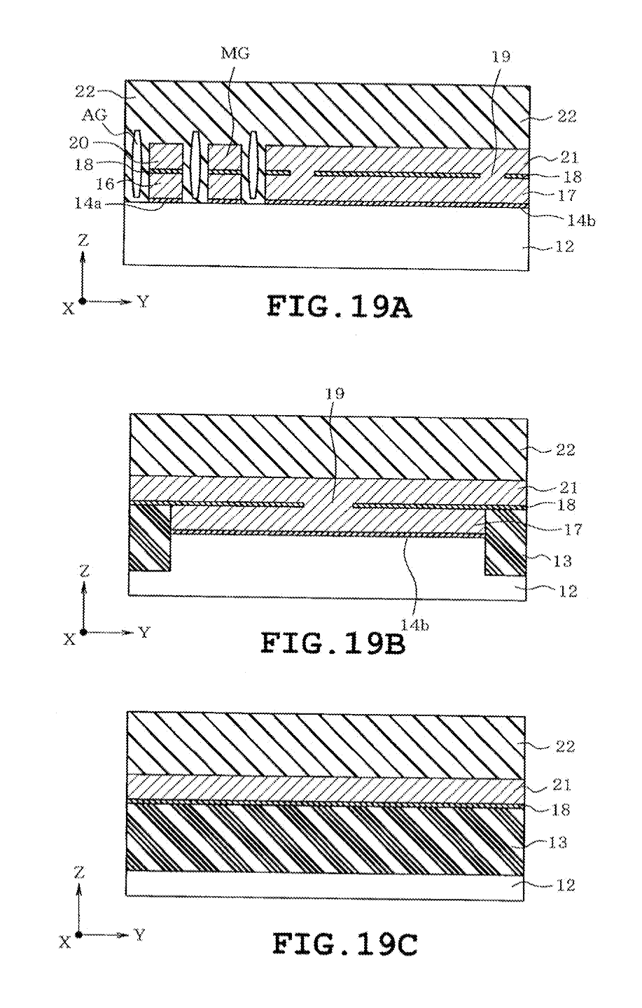

First, the processes illustrated using FIGS. 8A, 8B, and 8C in the first embodiment will be embodied. Since the content thereof is common with the processes in the second embodiment, description will be omitted here. Subsequently, as illustrated in FIGS. 19A, 19B and 19C, the interlayer insulating film 22 is formed.

Bad coverage conditions are used in the film formation of the silicon oxide film. Accordingly, the air gaps AG are formed between the memory gates MG. In the second embodiment, the film thickness of the interlayer insulating film 22 is formed to be thick in comparison to the first embodiment.

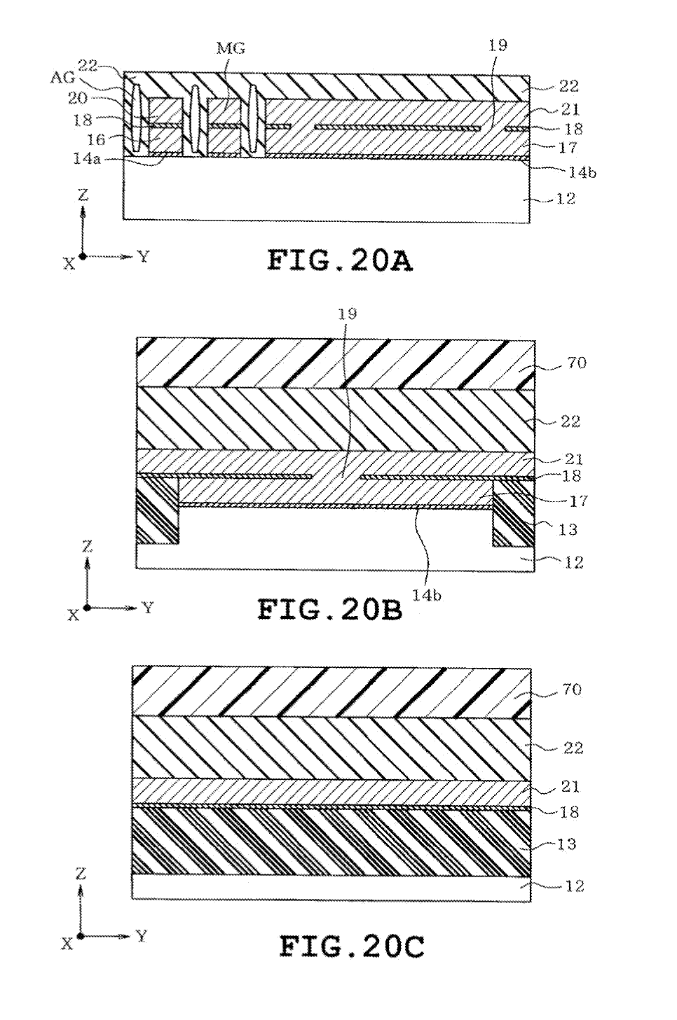

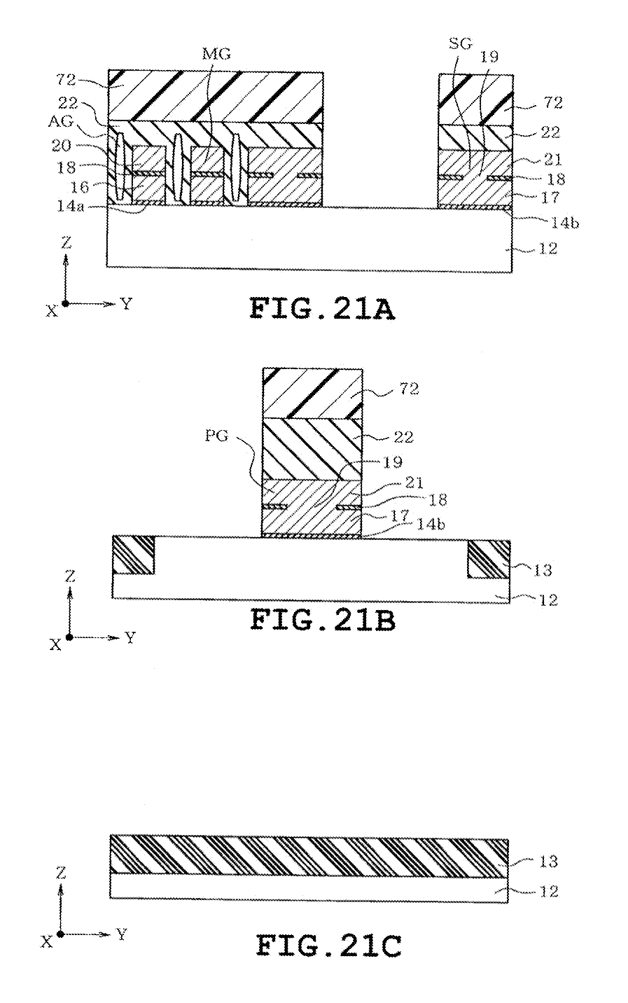

Next, as illustrated in FIGS. 20A, 20B, and 20C, using lithography, a resist 70 is formed to cover the entire surface of the upper portion of the peripheral circuit unit (including the ODT circuit unit) illustrated in FIGS. 20B and 20C, and is not formed on the memory cell area M illustrated in FIG. 21A. The interlayer insulating film 22 is thinned by etching the interlayer insulating film 22 of the memory cell area M using the RIE method with the resist 70 as a mask. Therefore, the film thickness of the interlayer insulating film 22 is formed to be thin in the memory cell area M and to be thick on the peripheral circuit unit. The film thickness of the interlayer insulating film 22 in the memory cell area M is formed to substantially the same film thickness as in the first embodiment, for example.

Next, as illustrated in FIGS. 21A, 21B and 21C, a resist 72 is formed using lithography, and the selected gate SG and the gate electrode PG are processed using the RIE method with the resist 72 as a mask. At this time, in the ODT circuit unit illustrated in FIG. 21C, since the resist 72 is not formed, the interlayer insulating film 22, the upper electrode 21 and the insulating film 18 are removed in relation to the entire surface of the area using etching, and the upper surface of the element isolation insulating film 13 is exposed.

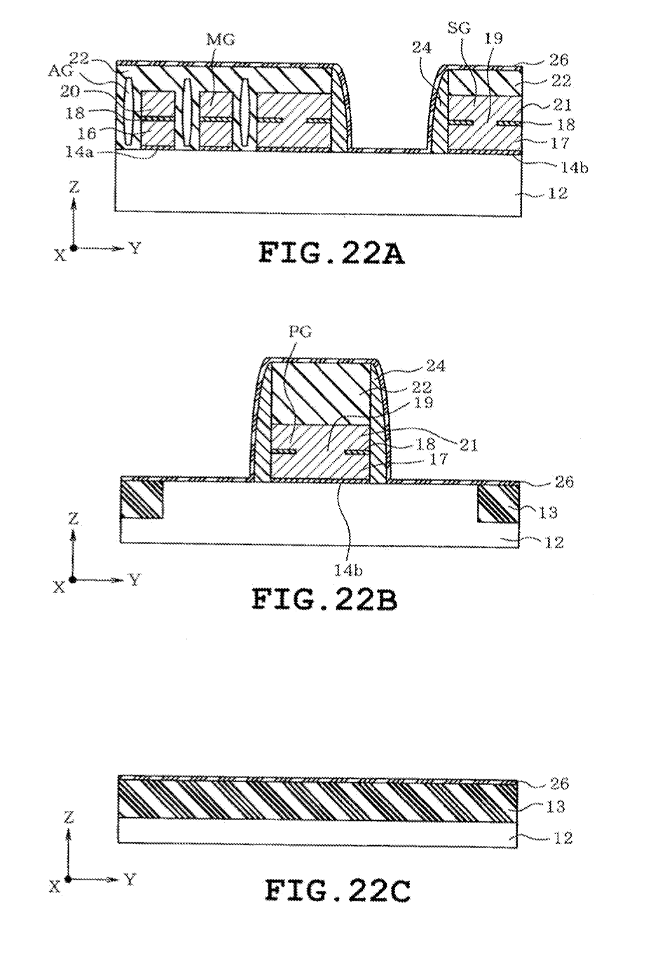

Next, as illustrated in FIGS. 22A, 22B, and 22C, the side wall insulating film 24 is formed on the side walls of the selected gate SG and the gate electrode PG. Next, the liner film 26 is formed on the semiconductor substrate 12, the memory gate MG, the gate electrode PG, and the surface of the element isolation insulating film 13. A silicon nitride film may be used, for example, as the liner film 26.

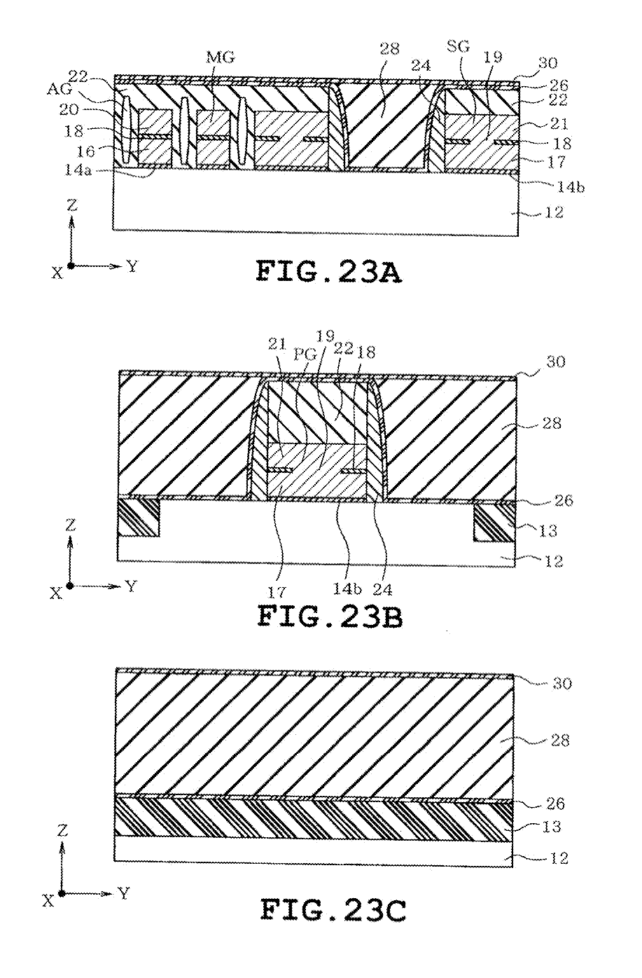

Next, as illustrated in FIGS. 23A, 23B, and 23C, the interlayer insulating film 28 is formed; and next, the upper surface is planarized using the CMP method. In the polishing process using the CMP method, the liner film 26 is used as the polishing stopper. Next, the barrier film 30 is formed. A silicon nitride film may be used, for example, as the barrier film 30. Here, the barrier film 30 is formed using a film of the same material as the liner film 26. In the present embodiment, silicon nitride films are used for both.

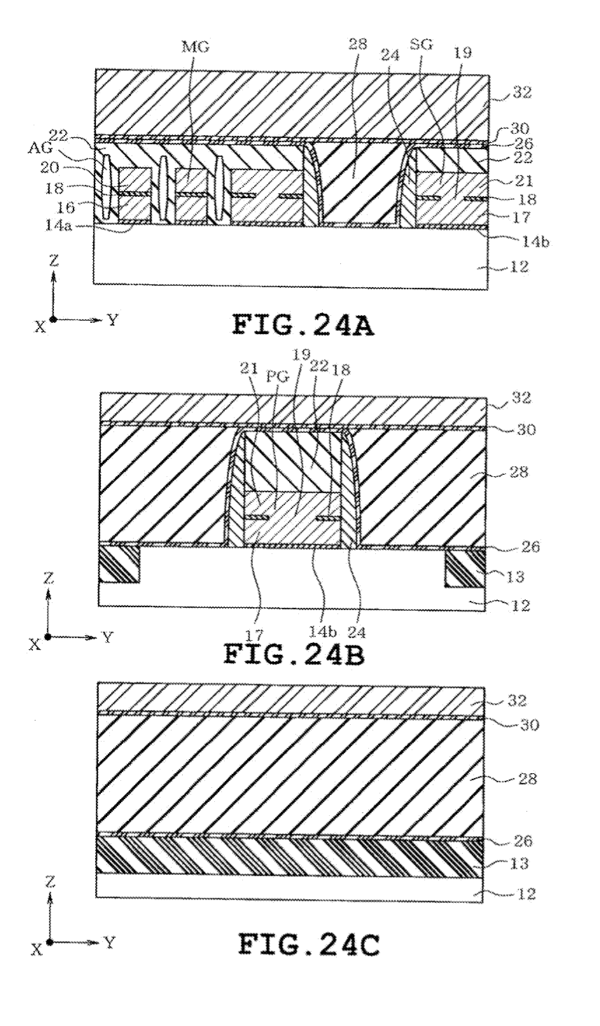

Next, as illustrated in FIGS. 24A, 24B, and 24C, the interlayer insulating film 32 is formed; and subsequently, the upper surface is planarized using the CMP method, for example.

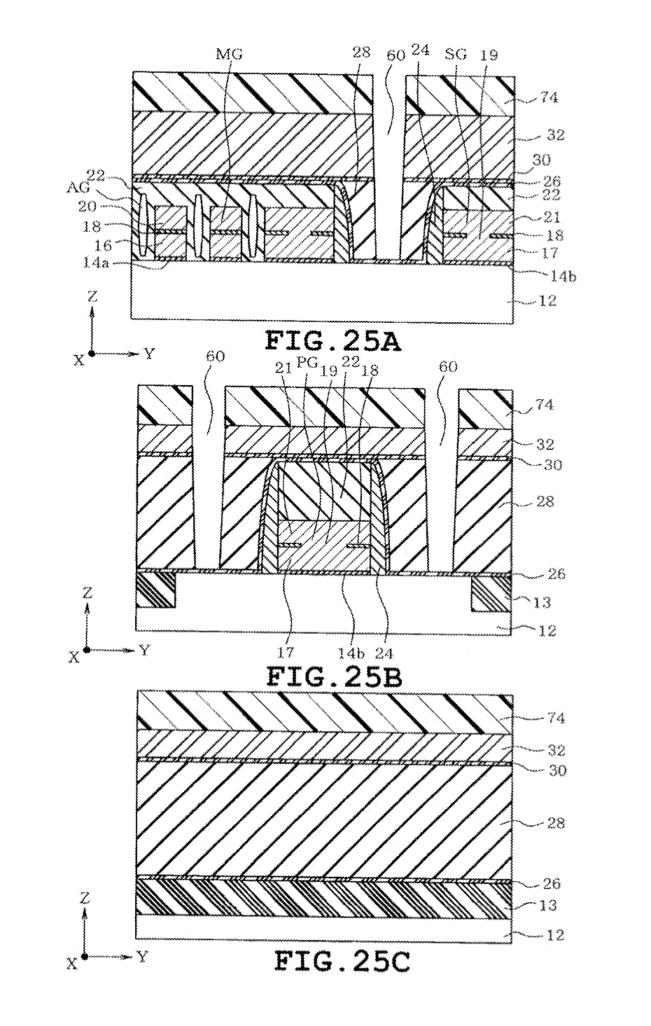

Next, as illustrated in FIGS. 25A, 25B and 25C, a resist 74 is formed using lithography; and next, the contact holes 60 are formed using the RIE method with the resist 74 as a mask. The contact holes 60 are formed by etching the interlayer insulating film 32, the barrier film 30, and the interlayer insulating film 28. In the etching step of the interlayer insulating film 28, the etching is performed under conditions of a high selection ratio between the silicon oxide film of the interlayer insulating film 28 and the silicon nitride film of the liner film 26, and is performed so as to stop on the liner film 26.

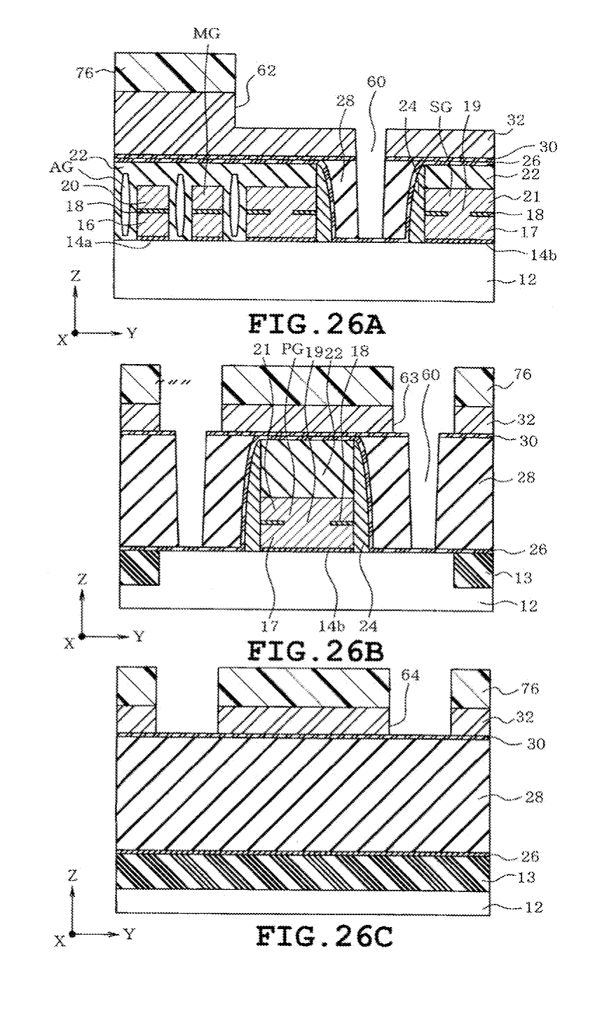

Next, as illustrated in FIGS. 26A, 26B and 26C, a resist 76 is patterned using lithography; and next, the wiring groove 62 of the memory cell area M, the wiring groove 63 of the transistor Trp forming area, and the wiring groove 64 of the ODT circuit unit are formed using the RIE method with the resist 76 as a mask. In the present embodiment, the wiring grooves 62, 63, and 64 are formed at the same time. In the transistor Trp forming area of the peripheral circuit unit illustrated in FIG. 26B and the ODT circuit unit illustrated in FIG. 26C, the wiring grooves 63 and 64 are etched using the barrier film 30 as a stopper film.

In the etching step of the interlayer insulating film 32, the etching is performed under conditions of a high selection ratio between the silicon oxide film of the interlayer insulating film 32 and the silicon nitride film of the barrier film 30, and is performed so as to stop on the barrier film 30. Accordingly, since the lower surface of the wiring groove 64 of the ODT circuit unit illustrated in FIG. 26C is substantially matched with the height of the upper surface of the barrier film 30, the variation in the depth of the wiring groove 64 of the peripheral circuit unit (including the ODT circuit unit) may be reduced.

The wiring groove 62 of the memory cell area M illustrated in FIG. 26A is formed to a depth which reaches the height of the barrier film 30 of the transistor Trp forming area of the peripheral circuit unit illustrated in FIG. 26B and the ODT circuit unit illustrated in FIG. 26C. Note that, since the liner film 26, which is exposed at the bottom surface of the contact hole 60, is formed using a silicon nitride film as described above, the liner film 26 functions as the stopper in the etching, and prevents the semiconductor substrate 12, which is below the liner film 26, from being exposed.

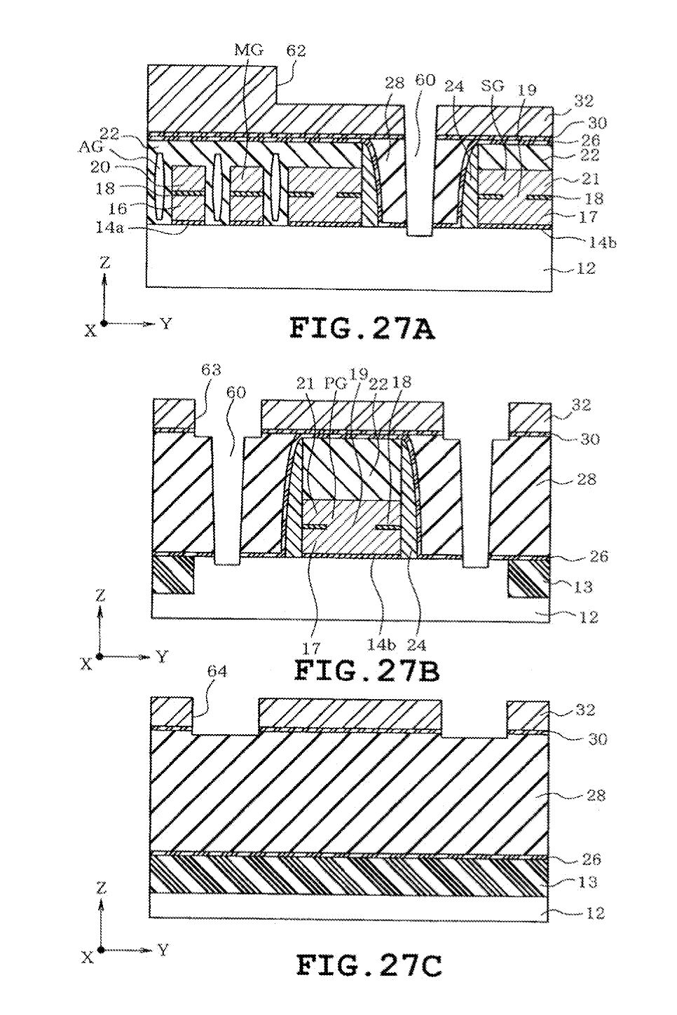

Next, as illustrated in FIGS. 27A, 27B, and 27C, after peeling off the resist 74, etching is performed using the RIE method, the liner film 26 (a silicon nitride film in the present embodiment) of the lower surfaces of the contact holes 60 is removed, and the surface of the semiconductor substrate 12 is exposed. At this time, the barrier film 30 (a silicon nitride film in the present embodiment) of the lower surface of the wiring groove 63 of the transistor Trp forming area and the lower surface of the wiring groove 64 of the ODT circuit unit is removed by etching at the same time.

In addition, a rut (a concave portion) may be formed in the surface of the semiconductor substrate 12 of the lower portion of the contact holes 60 by over etching in the etching. In addition, a rut (a concave portion) may be formed in the surface of the interlayer insulating film 28 of the lower portion of the wiring groove 64 of the ODT circuit unit by over etching in the etching.

Next, as illustrated in FIGS. 18A, 18B, and 18C, the inside of the contact holes 60, and the inside of the wiring grooves 62, 63, and 64 are filled by forming a metal film such as tungsten on the entire surface of the semiconductor substrate 12 using the CVD method or the like. Next, the surface of the interlayer insulating film 32 is exposed by removing, by polishing, the stacked metal using the CMP method, and the contact plugs 34, 38 and the wirings 36, 40, 42 are formed. In other words, the contact plugs 34, 38, and the wirings 36, 40, 42 are formed using the so-called damascene process.

As described above, the contact plug 34 and the wiring 36, and the contact plug 38 and the wiring 40 are formed integrally. In addition, the metal film may be a stacked film of titanium nitride and tungsten. In this case, the titanium nitride functions as a barrier metal film.

In the above processes, the NAND flash memory device 100 according to the present embodiment is formed. According to the present embodiment, the same effect is obtained as in the first embodiment.

### Other Embodiments

Besides those described in the above embodiments, the following modifications may be made.

Description is given exemplifying an example which uses so-called via-first damascene technology in which, in the formation of the contact plugs and the wirings, the contact holes are formed first; however, instead of this, a so-called trench-first damascene technology in which the contact holes are formed after forming the wiring grooves first may be used.

In addition, the present embodiment may also be applied to a structure in which there is no barrier film 30. For example, the liner film 26 may be used instead of the barrier film 30 as the stopper film of the etching process of the wirings 40 and 42 (the wiring grooves 63 and 64). However, in this case, it is necessary to dispose the gate electrodes and the like below the wirings where depth variation is to be suppressed. The gate electrodes may be dummies.

In addition, in the above embodiments, an example in which the embodiment is applied to a NAND flash memory device is illustrated; however, in addition, the embodiment may be applied to a NOR flash memory device, a nonvolatile semiconductor memory device such as EPROM, semiconductor memory devices such as DRAM or SRAM, or a logical semiconductor device such as a micro computer.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a semiconductor substrate having a memory cell region and a peripheral circuit region;
a plurality of adjacent memory gates that are disposed on the semiconductor substrate via a tunnel insulating film in the memory cell region;
a first insulating film covering the memory gates and having air gaps formed therein between the memory gates;
a first barrier film on the first insulating film;
a second insulating film above the semiconductor substrate in the peripheral circuit region;
a second barrier film on the first barrier film and the second insulating film; and
a third insulating film on the second barrier film and having a first groove, in which a first wiring is formed above the memory cell region, and a second groove in which a second wiring is formed above the peripheral circuit region,
wherein a distance between a lower surface of the first wiring and an upper surface of the semiconductor substrate in the memory cell region is larger than a distance between an upper surface of the first barrier film and the upper surface of the semiconductor substrate in the memory cell region, and a lower surface of the second wiring is closer to the upper surface of the semiconductor substrate in the peripheral circuit region than an upper surface of the second barrier film.

2. The device according to claim 1,
wherein the second wiring includes a first portion and a second portion, and a film thickness of the first portion is larger than a film thickness of the first wiring.

3. The device according to claim 2,
wherein a film thickness of the second portion is the same as the film thickness of the first wiring.

4. The device according to claim 2,
wherein the first portion and the second portion of the second wiring are separated from each other.

5. The device according to claim 4, further comprising:
a third wiring above the second wiring,
wherein the first portion and the second portion of the second wiring are connected by the third wiring.

6. The device according to claim 1,
wherein a film thickness of the second wiring is equal to a film thickness of the first wiring.

7. The device according to claim 1,
wherein a side surface of the second wiring contacts the second barrier film.

8. The device according to claim 1,
wherein the second barrier film is farther from the semiconductor substrate than the first barrier film.

9. The device according to claim 1,
wherein the first barrier film and the second barrier film are made of a same material.

10. The device according to claim 1, further comprising:
a transistor disposed in the peripheral circuit region and including a gate insulating film and a gate electrode,
wherein a distance from an upper surface of the tunnel insulating film to an upper surface of the second barrier film is equal to a distance from an upper surface of the gate insulating film to an upper surface of the second barrier film.

11. The device according to claim 1,
wherein the second wiring includes a first portion and a second portion, and wherein a lower surface of the second portion contacts a contact plug, and a lower surface of the second portion is farther from the second barrier film than a lower surface of the first portion.

12. The device according to claim 1,
wherein the second wiring includes a first portion and a second portion, and
wherein a contact plug contacts a lower surface of the second portion, and a lower surface of the second portion is equal distance away from the second barrier as a lower surface of the first portion.

13. The device according to claim 1, further comprising:
a transistor is disposed in the peripheral circuit region, and including a gate insulating film and a gate electrode,
wherein a distance from an upper surface of the tunnel insulating film to an upper surface of the first wiring is equal to a distance from an upper surface of the gate insulating film to an upper surface of the second wiring.

14. A semiconductor memory device, comprising:
a semiconductor substrate having a memory cell region and a peripheral circuit region;
a plurality of adjacent memory gates that are disposed on the semiconductor substrate via a tunnel insulating film in the memory cell region;
a first insulating film covering the memory gates and having air gaps formed therein between the memory gates;
a second insulating film above the semiconductor substrate in the peripheral circuit region;
a barrier film formed above the first and second insulating films; and
a third insulating film on the barrier film and having a first groove, in which a first wiring is formed above the memory cell region, and a second groove in which a second wiring is formed above the peripheral circuit region,
wherein a lower surface of the second wiring is closer to the upper surface of the semiconductor substrate in the peripheral circuit region than an upper surface of the barrier film.

15. The device according to claim 14,
wherein a lower surface of the first wiring is farther from an upper surface of the semiconductor substrate in the memory cell region than an upper surface of the barrier film.

16. The device according to claim 14,
wherein the barrier film is closer to an upper surface of the semiconductor substrate in the memory cell region than to an upper surface of the semiconductor substrate in the peripheral circuit region.

17. A method of forming a semiconductor memory device having a semiconductor substrate divided into a memory cell region and a peripheral circuit region, comprising:
forming a plurality of adjacent memory gates on the semiconductor substrate in the memory cell region via a tunnel insulating film;
covering the memory gates with a first insulating film such that air gaps are formed between the memory gates;
depositing a second insulating film above the semiconductor substrate in the peripheral circuit region;
forming a barrier film on the first and second insulating films;
depositing a third insulating film on the barrier film and forming first and second grooves therein; and
forming a first wiring in the first groove above the memory cell region, and a second wiring in the second groove above the peripheral circuit region,
wherein a lower surface of the second wiring is closer to the upper surface of the semiconductor substrate in the peripheral circuit region than an upper surface of the barrier film.

18. The method according to claim 17,
wherein a lower surface of the first wiring is farther from an upper surface of the semiconductor substrate in the memory cell region than an upper surface of the barrier film.

19. The method according to claim 17,
wherein the barrier film is closer to an upper surface of the semiconductor substrate in the memory cell region than to an upper surface of the semiconductor substrate in the peripheral circuit region.

20. The method according to claim 17, further comprising:
forming liner film made of the same material as the barrier film on the first insulating film and on the semiconductor substrate in the peripheral circuit region prior to forming the barrier film.
